(19) United States
(12) Patent Application Publication
(10) Pub. No.: US 2025/0046676 A1
(43) Pub. Date: Feb. 6, 2025

(54) SEMICONDUCTOR DEVICE

(71) Applicant: FUJI ELECTRIC CO., LTD., Kawasaki-shi (JP)

(72) Inventor: Daiki SANO, Matsumoto-city (JP)

(73) Assignee: FUJI ELECTRIC CO., LTD., Kawasaki-shi (JP)

(21) Appl. No.: 18/756,248

(22) Filed: Jun. 27, 2024

(30) Foreign Application Priority Data
Aug. 3, 2023 (JP) 2023-126824

(51) Int. Cl. H01L 23/473; H01L 23/00; H01L 23/31; H01L 23/36; H01L 23/538; H01L 25/065

(52) U.S. Cl. CPC H01L 23/473; H01L 23/36; H01L 25/0655; H01L 23/3107; H01L 23/5383; H01L 24/29; H01L 24/32; H01L 2224/29111; H01L 2224/32225

(57) ABSTRACT

A semiconductor device, including: a semiconductor chip formed on a heat dissipation plate; a pool part including a bottom surface, two long lateral faces, and two short lateral faces defining a pool space; a guide part installed in the pool space and having first and second ends both connected to one of the short lateral face, at positions opposite to each other across an inlet formed on the one short lateral face, so as to separate a guide space from the pool space; and a guide plate disposed in the pool space on the guide part. In the plan view, the guide plate has a slit formed within an area thereof overlapping the guide space. The heat dissipation plate is disposed on the pool part. A geometrical area of a cross-section of the guide space becomes smaller as the cross-section is farther away from the inlet of the pool part.

### CROSS-REFERENCE TO RELATED APPLICATION

This application is based upon and claims the benefit of priority of the prior Japanese Patent Application No. 2023-126824, filed on Aug. 3, 2023, the entire contents of which are incorporated herein by reference.

### BACKGROUND OF THE INVENTION

### 1. Field of the Invention

The embodiments discussed herein relate to a semiconductor device.

### 2. Background of the Related Art

In cooling devices, objects to be cooled are placed on the front surface. To cool the objects, the cooling devices cause a refrigerant to flow through the interior (see, for example, Japanese Laid-open Patent Publications No. 2014-116404, No. 2017-174991, and No. 2013-058518). Semiconductor devices include such a cooling device and a semiconductor module, which is an object to be cooled, disposed on the cooling device (see, for example, International Publication Pamphlet No. WO 2012/147544).

### SUMMARY OF THE INVENTION

According to an aspect, there is provided a semiconductor device, including: a semiconductor chip; a heat dissipation plate, having: a front surface including a placement area, a rear surface having a cooling area corresponding to the placement area, and a plurality of fins provided in the cooling area; the semiconductor chip being disposed in the placement area; a pool part, including: a bottom surface having a rectangular shape in a plan view of the semiconductor device, a pair of long lateral faces, and a first short lateral face and a second short lateral face, with an inlet formed on the first short lateral face, to thereby define a pool space surrounded by the bottom surface, the pair of long lateral faces and the first and second short lateral faces; a guide part configured to be installed in the pool space on the bottom surface, the guide part having a first end and a second end that are both connected to an inner side of the first short lateral face, at positions opposite to each other across the inlet, so as to separate a guide space from the pool space, the guide space communicating with the inlet; and a guide plate disposed in the pool space on the guide part, the guide plate having a shape of a flat plate with a slit, wherein in the plan view of the semiconductor device, the guide plate is positioned to have two gaps on two opposite sides thereof, respectively between the guide plate and the pair of long lateral faces, and the slit is formed within an area of the guide plate overlapping the guide space; the rear surface of the heat dissipation plate is disposed on the pool part in such a manner that the plurality of fins is housed in the pool space and over the guide plate; and the guide part is installed such that a geometrical area of a cross-section of the guide space becomes smaller as the cross-section is farther away from the inlet of the pool part.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a lateral view of the semiconductor device of the first embodiment;

FIG. 3 is an exploded perspective view of a cooling device of the first embodiment;

FIG. 4 is a plan view of the cooling device (excluding a guide plate) of the first embodiment;

FIG. 5 is a cross-sectional view of the cooling device (excluding the guide plate) of the first embodiment;

FIG. 6 is another plan view of the cooling device of the first embodiment;

FIG. 7 is another cross-sectional view of the cooling device of the first embodiment;

FIG. 8 is a back view of a heat dissipation plate of the first embodiment;

FIG. 9 is a first cross-sectional view of the semiconductor device of the first embodiment;

FIG. 10 is a second cross-sectional view of the semiconductor device of the first embodiment;

FIG. 11 is a first plan view illustrating a refrigerant flow in the cooling device of the first embodiment;

FIG. 12 is a first cross-sectional view illustrating the refrigerant flow in the cooling device of the first embodiment;

FIG. 13 is a second plan view illustrating the refrigerant flow in the cooling device of the first embodiment;

FIG. 14 is a second cross-sectional view illustrating the refrigerant flow in the cooling device of the first embodiment;

FIG. 15 is a third plan view illustrating the refrigerant flow in the cooling device of the first embodiment;

FIG. 16 is a plan view of a cooling device (excluding a guide plate) of a reference example;

FIG. 17 is another plan view of the cooling device of the reference example;

FIG. 18 is a plan view of a cooling device (excluding a guide plate) of a second embodiment;

FIG. 19 is a cross-sectional view of the cooling device (excluding the guide plate) of the second embodiment;

FIG. 20 is a plan view of a cooling device (excluding a guide plate) of a third embodiment;

FIG. 21 is a cross-sectional view of the cooling device (excluding the guide plate) of the third embodiment;

FIG. 22 is another plan view of the cooling device of the third embodiment;

FIG. 23 is a cross-sectional view of a cooling device (excluding a guide plate) of a fourth embodiment;

FIG. 24 is a plan view of the cooling device of the fourth embodiment;

FIG. 25 is a plan view of a cooling device (excluding a guide plate) of a fifth embodiment;

FIG. 26 is another plan view of the cooling device of the fifth embodiment;

FIG. 27 is a graph plotting temperature of semiconductor chips relative to their placement positions; and

FIG. 28 is a graph of pressure drop.

### DETAILED DESCRIPTION OF THE INVENTION

Several embodiments will be described below with reference to the accompanying drawings. Note that in the following the terms “front surface” and “top face” refer to the X-Y plane facing upward (the +Z direction) in a semiconductor device 1 of the drawings. Similarly, the term “upper” refers to the upward direction (the +Z direction) of the illustrated semiconductor device 1. On the other hand, the terms “rear surface” and “bottom face” refer to the X-Y plane facing downward (the −Z direction) in the illustrated semiconductor device 1. Similarly, the term “lower” refers to the downward direction (the −Z direction) of the illustrated semiconductor device 1. These terms have the same orientational relationships in other drawings if needed. “High” and “upper” in position refer to upper positions (the +Z direction) in the illustrated semiconductor device 1. On the other hand, “low” and “lower” in position refer to lower positions (the −Z direction) in the illustrated semiconductor device 1. The terms “front surface”, “top face”, and “upper”; the terms “rear surface”, “bottom face”, and “lower”; and the term “lateral face” are simply expedient expressions used to specify relative positional relationships, and are not intended to limit the technical ideas of the embodiments described herein. For example, the terms “upper” and “lower” do not necessarily imply the vertical direction to the ground surface. That is, the “upper” and “lower” directions are not defined in relation to the direction of the gravitational force. In addition, the term “major component” in the following refers to a constituent having a concentration equal to 80 vol % or higher. The phrase “substantially the same” refers to where two or more things being compared have a difference of no more than ±10%. In addition, the terms “perpendicular”, “orthogonal”, and “parallel” may also include substantially perpendicular, substantially orthogonal, and substantially parallel, as appropriate, which may include a margin of error of ±10° or less.

### (a) First Embodiment

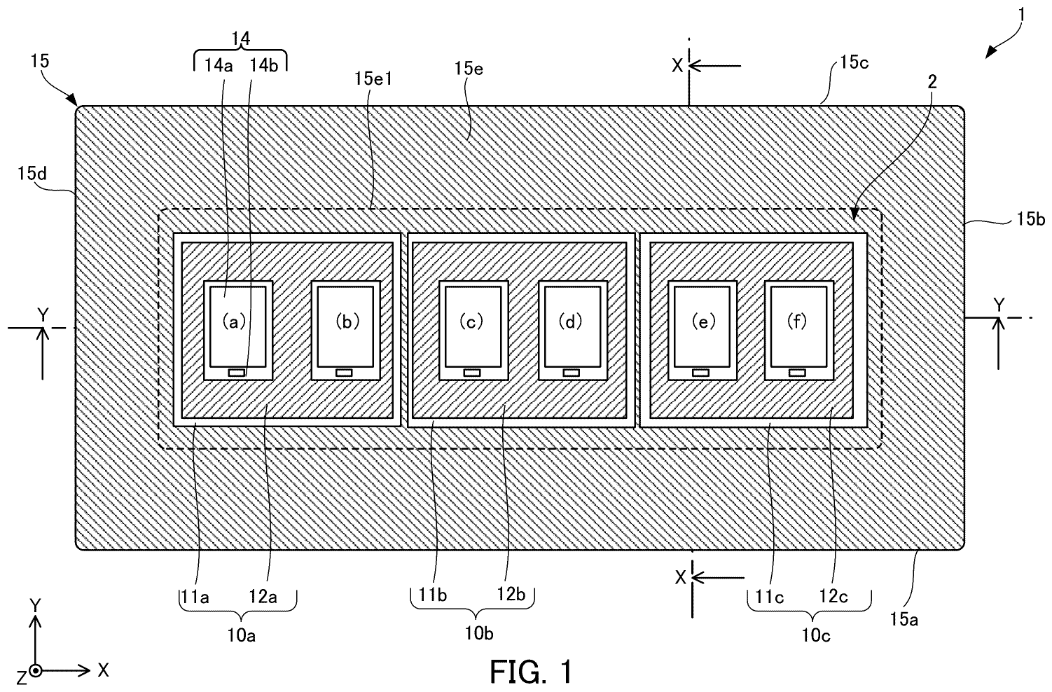

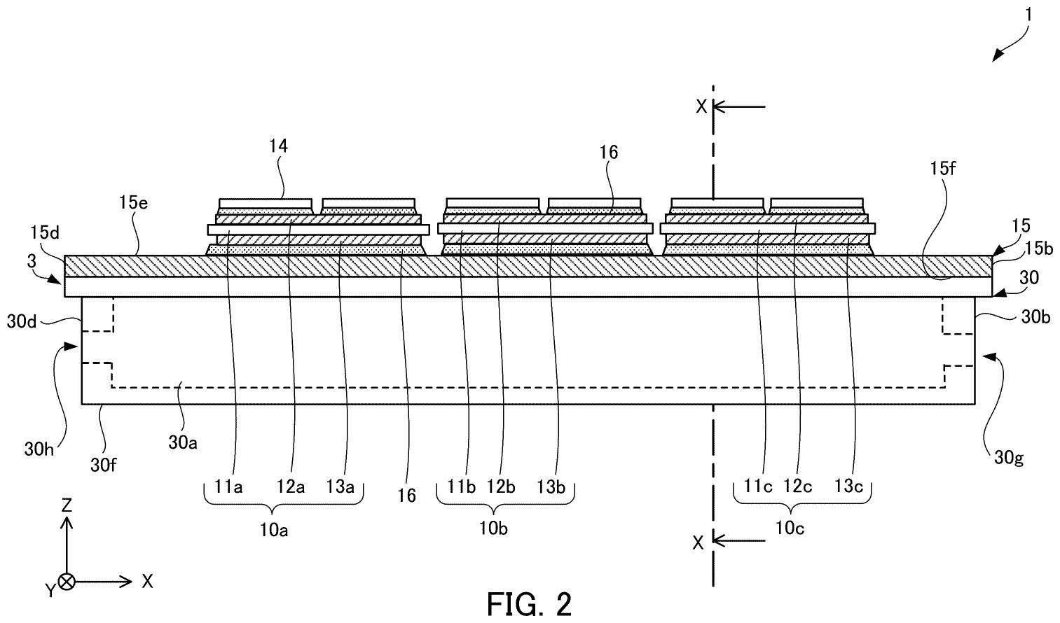

Next described is a semiconductor device with reference to FIGS. 1 and 2. FIG. 1 is a plan view of a semiconductor device according to a first embodiment. FIG. 2 is a lateral view of the semiconductor device of the first embodiment. Note that the lateral view of FIG. 2 is obtained when the semiconductor device 1 of FIG. 1 is viewed in the +Y direction.

The semiconductor device 1 includes a semiconductor unit 2, a heat dissipation plate 15, and a cooling device 3, as depicted in FIGS. 1 and 2. The semiconductor unit 2 includes insulated circuit boards 10a, 10b, and 10c and semiconductor chips 14 each disposed on the front surface of the insulated circuit board 10a, 10b, or 10c via a bonding member 16. The insulated circuit boards 10a, 10b, and 10c include insulating plates 11a, 11b, and 11c, respectively; conductive patterns 12a, 12b, and 12c, respectively, provided on the front surfaces of the insulating plates 11a, 11b, and 11c; and metal plates 13a, 13b, and 13c, respectively, provided on the rear surfaces of the insulating plates 11a, 11b, and 11c. Note that the term “insulated circuit boards 10” may be used in the following description when no distinction is made among the insulated circuit boards 10a, 10b, and 10c. Similarly, the terms “insulating plates 11”, “conductive patterns 12”, and “metal plates 13” are used when no distinction needs to be made among the insulating plates 11a, 11b, and 11c, the conductive patterns 12a, 12b, and 12c, and the metal plates 13a, 13b, and 13c, respectively.

The insulating plates 11 and the metal plates 13 have a rectangular shape in plan view. In addition, the insulating plates 11 and the metal plates 13 may have R- or C-chamfered corners. The individual metal plates 13 are smaller in size than the insulating plates 11, and are thus formed inside the insulating plates 11 in plan view.

The insulating plates 11 may be, for example, ceramic boards. The ceramic boards are made of ceramic with excellent thermal conductivity. The ceramic here is a material whose major component is, for example, aluminum oxide, aluminum nitride, or silicon nitride. The insulating plates 11 have a rectangular shape in plan view.

The conductive patterns 12 are respectively formed all over the corresponding insulating plates 11, except for their rims. Preferably, in plan view, edges of each of the conductive patterns 12, facing the outer periphery of the insulating plate 11 coincide with those of the metal plate 13, facing the outer periphery of the insulating plate 11. For this reason, the insulated circuit boards 10 maintain stress balance between the insulating plates 11 and the metal plates 13 placed on the rear surfaces of the insulating plates 11. This reduces damage to the insulating plates 11, such as excessive warpage and crack formation. The conductive patterns 12 are made of a material with excellent electrical conductivity. The material is, for example, copper, aluminum, or an alloy containing at least one of these. In order to provide improved corrosion resistance, plating may be applied to coat the surfaces of the conductive patterns 12. In this case, a material used for plating is, for example, nickel, a nickel-phosphorus alloy, or a nickel-boron alloy. The conductive patterns 12 on the insulating plates 11 are created by forming metal plates on the front surfaces of the insulating plates 11 and performing etching or the like on the metal plates. Alternatively, the conductive patterns 12 preliminarily cut out of metal plates are pressure bonded to the front surfaces of the insulating plates 11. Note that the conductive patterns 12 included in the semiconductor device 1 of the first embodiment are merely an example, and appropriate changes may be made to the number of conductive patterns, their shape, size and so on, as needed basis.

The metal plates 13 are made of a metal with excellent thermal conductivity. The metal is, for example, copper, aluminum, or an alloy containing at least one of these. Here, the metal contains copper. In order to provide improved corrosion resistance, plating may be applied to coat the surfaces of the metal plates 13. In this case, a material used for plating includes nickel. The plating material is, for example, nickel, a nickel-phosphorus alloy, or a nickel-boron alloy.

As the insulated circuit boards 10 having the above-described configuration, for example, direct copper bonding (DCB) boards or active metal brazed (AMB) boards may be used. The insulated circuit boards 10 conduct heat generated in semiconductor chips 14 to be described later to the rear surfaces of the insulated circuit boards 10 via the conductive patterns 12, the insulating plates 11, and the metal plates 13 and then dissipate the heat.

The semiconductor chips 14 include a switching element whose major component is, for example, silicon. The switching element is, for example, a reverse-conducting insulated gate bipolar transistor (RC-IGBT). The RC-IGBT has a single-chip structure with a circuit where a free wheeling diode (FWD) is connected antiparallel to an IGBT.

Each of the semiconductor chips 14 has, on its rear surface, a collector electrode as an input electrode, and also has, on its front surface, a gate electrode as a control electrode 14b and an emitter electrode as an output electrode 14a. The control electrode 14b may be provided at the center of one side of the front surface of the semiconductor chip 14. Note however that the control electrode 14b does not necessarily have to be located in the center of one side of the front surface of the semiconductor chip 14, and may be displaced from the center in the ±X direction.

Alternatively, instead of the RC-IGBT, each of the semiconductor chips 14 may use, as the switching element, a power metal-oxide-semiconductor field-effect transistor (MOSFET) whose major component is silicon carbide. In the power MOSFET, a body diode functions as an FWD. The semiconductor chip 14 of this type has, for example, a drain electrode as an input electrode on its rear surface, and a gate electrode as the control electrode 14b and a source electrode as the output electrode 14a on the front surface.

Instead of the semiconductor chips 14, different semiconductor chips may be used, each of which has silicon as its major component and includes a pair of a switching element and a diode element. The switching element is, for example, a power MOSFET or IGBT. Each semiconductor chip including such a switching element, for example, has an input electrode (a drain electrode in the case of a power MOSFET, and a collector electrode in the case of an IGBT) on the rear surface, and has the control electrode 14b (a gate electrode) and the output electrode 14a (a source electrode in the case of a power MOSFET, and an emitter electrode in the case of an IGBT) on the front surface. On the other hand, as for the diode element, for example, a Schottky barrier diode (SBD) or a P-intrinsic-N (PiN) diode is used as an FWD. The semiconductor chips including such a diode element have an output electrode (cathode electrode) functioning as a main electrode on the rear surface, and have an input electrode (anode electrode) functioning as a main electrode on the front surface.

The rear surface of each of the semiconductor chips 14 is bonded onto the conductive pattern 12 via the bonding member 16. The bonding member 16 is solder or a sintered compact. The solder used is lead-free solder containing a predetermined alloy as a major component. The predetermined alloy includes tin. Such an alloy is, for example, at least one of the followings: a tin-silver-copper alloy, a tin-zinc-bismuth alloy, a tin-copper alloy, a tin-silver-indium-bismuth alloy, and a tin-antimony alloy. Further, the solder may include an additive, such as nickel, germanium, cobalt, or silicon. In addition, the sintered material used in bonding by sintering is, for example, powder of silver, iron, copper, aluminum, titanium, nickel, tungsten, or molybdenum.

The heat dissipation plate 15 includes a front surface 15e having a rectangular shape in plan view; a rear surface 15f opposite to the front surface 15e; and a long lateral face 15a, a short lateral face 15b, a long lateral face 15c, and a short lateral face 15d surrounding in order all four sides of the front surface 15e and the rear surface 15f. On the front surface 15e of the heat dissipation plate 15, a unit area 15e1 is provided in which the semiconductor unit 2 is disposed. The insulated circuit boards 10a, 10b, and 10c of the semiconductor unit 2 are arranged in the unit area 15e1 of the front surface 15e, in a line along the long lateral faces 15a and 15c. At this time, the metal plates 13 of the insulated circuit boards 10 are bonded to the front surface 15e with the above-described bonding member 16. The heat dissipation plate 15 is made of a metal with excellent electrical conductivity. The metal is, for example, copper, aluminum, or an alloy containing at least one of these. Here, the metal contains copper. In order to provide improved corrosion resistance, plating may be applied to coat the surface of the heat dissipation plate 15. In this case, a material used for plating includes nickel. The plating material is, for example, nickel, a nickel-phosphorus alloy, or a nickel-boron alloy. Details of the heat dissipation plate 15 will be described later.

Note that, in the first embodiment, by disposing the semiconductor unit 2 on the heat dissipation plate 15, the six semiconductor chips 14 are arranged in a line along the long lateral faces 15a and 15c of the heat dissipation plate 15. These semiconductor chips 14 are identified as (a) to (f) in order, starting from the one closest to an outlet 30h to be described later.

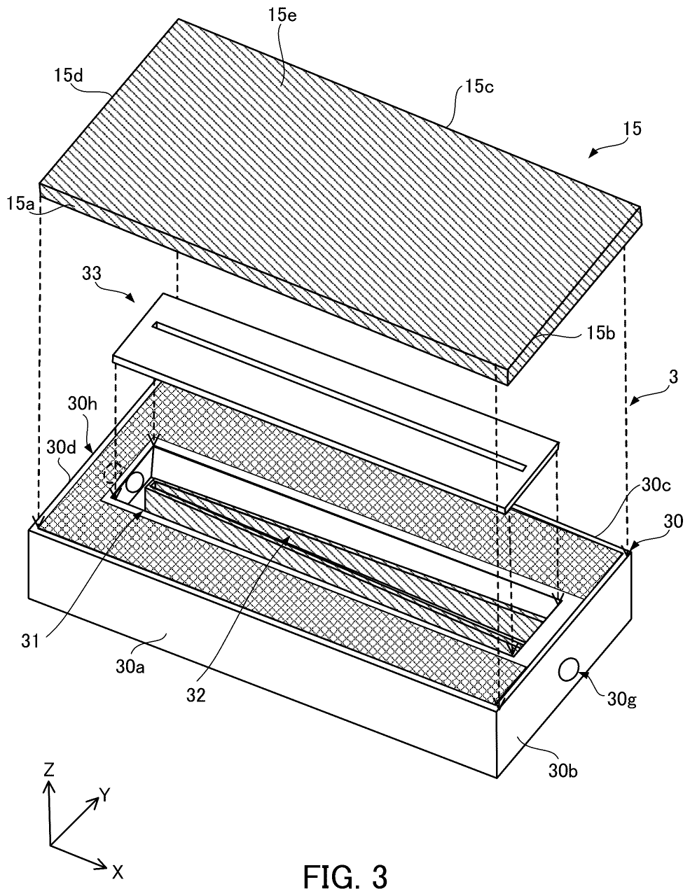

The cooling device 3 is provided on the rear surface 15f of the heat dissipation plate 15. The cooling device 3 includes a chassis 30. In plan view, the chassis 30 is disposed to oppose the heat dissipation plate 15, and includes a rectangular bottom plate 30f as well as a long lateral wall 30a, a short lateral wall 30b, a long lateral wall 30c, and a short lateral wall 30d, which surround the bottom plate 30f on all four sides in order (see FIG. 3). The long lateral wall 30a, the short lateral wall 30b, the long lateral wall 30c, and the short lateral wall 30d are the same in height. The rear surface 15f of the heat dissipation plate 15 is attached to the upper parts of the long lateral wall 30a, the short lateral wall 30b, the long lateral wall 30c, and the short lateral wall 30d. Outward barbs may be provided on the edges of the long lateral wall 30a, the short lateral wall 30b, the long lateral wall 30c, and the short lateral wall 30d in the +Z direction. Herewith, the area joined to the rear surface 15f of the heat dissipation plate 15 increases, which improves the adhesion to the rear surface 15f of the heat dissipation plate 15. An inlet 30g is formed on the short lateral wall 30b. An outlet 30h is formed on the short lateral wall 30d. The inlet 30g and the outlet 30h communicate with the inside of the chassis 30.

The cooling device 3 with the above configuration may include a pump and a heat dissipation device (radiator). The pump allows a refrigerant to flow into the inlet 30g of the cooling device 3, and the refrigerant flowing into the cooling device 3 from the inlet 30g circulates through the cooling device 3. The refrigerant absorbs heat from the semiconductor unit 2 while flowing through the cooling device 3. The refrigerant having circulated through the cooling device 3 flows out from the outlet 30h. The radiator receives the refrigerant flowing out from the cooling device 3 and radiates the heat removed from the semiconductor unit 2 and then absorbed by the refrigerant to the outside. The pump causes the heat-released refrigerant to flow into the cooling device 3 again through the inlet 30g and circulate inside the cooling device 3. Examples of the refrigerant used here include water, an antifreeze solution (ethylene glycol aqueous solution), and a long-life coolant. Details of the cooling device 3 will be described later.

The semiconductor device 1 may have a case (not illustrated) for housing the semiconductor unit 2, provided on the front surface 15e of the heat dissipation plate 15. In the case, for example, an N terminal, a P terminal, and an output terminal are integrally formed. These terminals are each connected to the semiconductor unit 2 in the case. In addition, within the semiconductor unit 2, the semiconductor unit 2 and various terminals may be connected by wiring members (not illustrated). The wiring members are, for example, wires and lead frames. Note that the case is formed by injection molding using a thermoplastic resin including a filler. Such a resin is, for example, polyphenylene sulfide (PPS); polybutylene terephthalate (PBT); or polyamide (PA). The filler contains, for example, glass fibers, glass beads, calcium carbide, talc, magnesium oxide, or aluminum hydroxide.

In addition, the inside of the case may be sealed with a sealing member. The sealing member is, for example, resin mixed with a filler. The a thermosetting thermosetting resin is, for example, epoxy resin, phenolic resin, maleimide resin, or polyester resin. The filler is ceramic with insulation properties and high thermal conductivity. Such a filler is, for example, silicon oxide, aluminum oxide, boron nitride, or aluminum nitride.

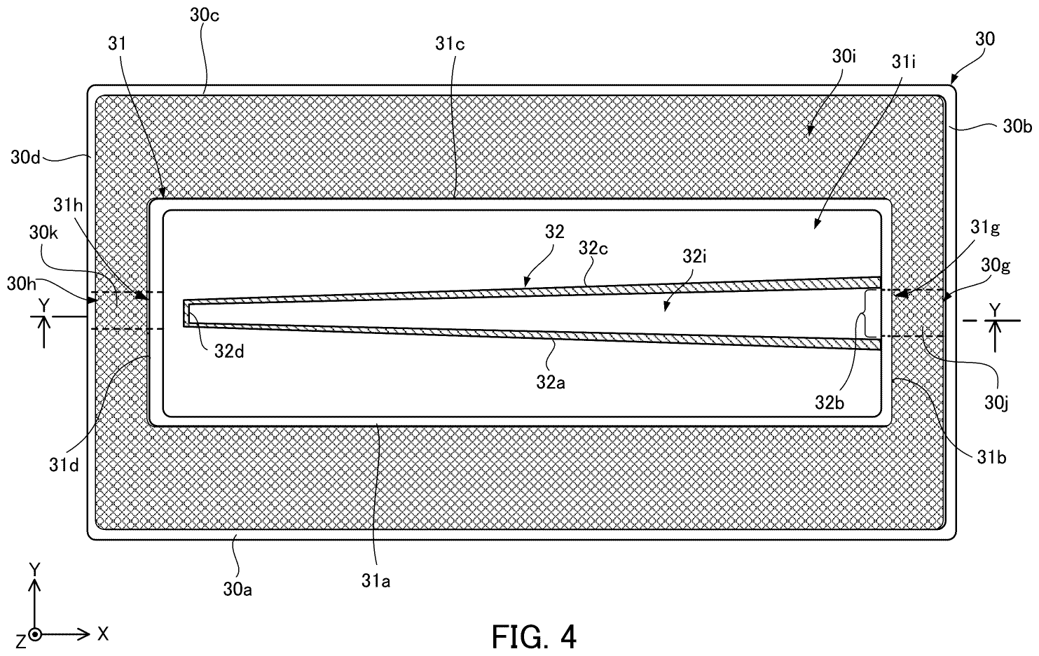

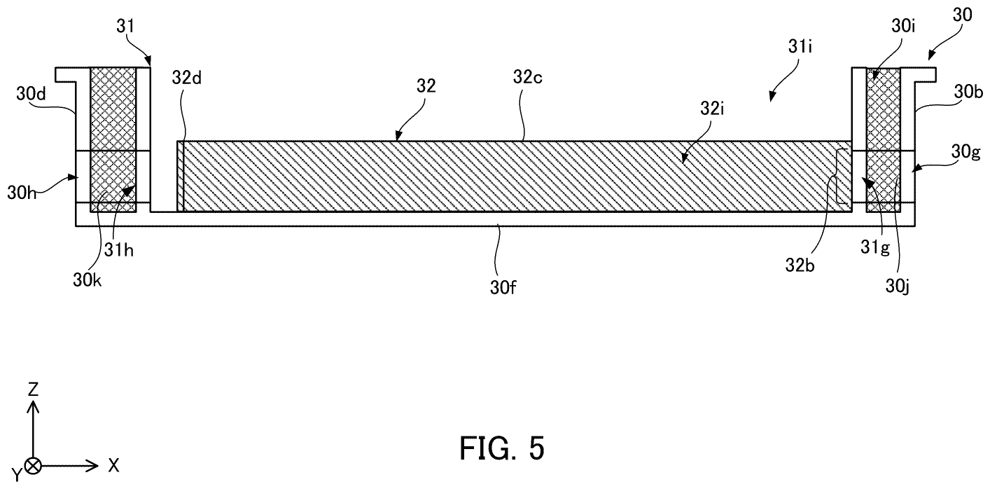

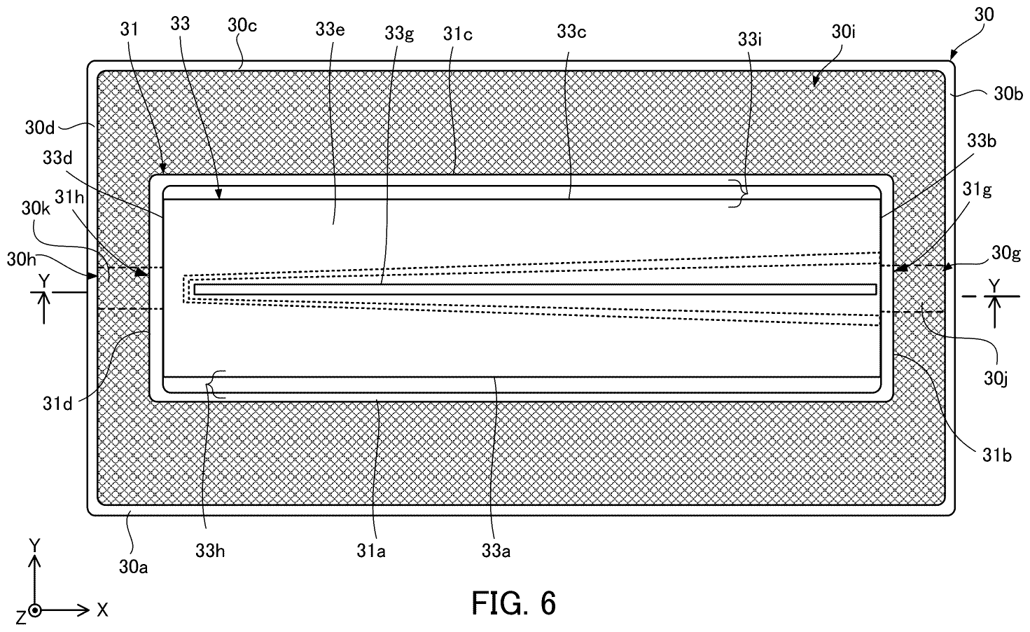

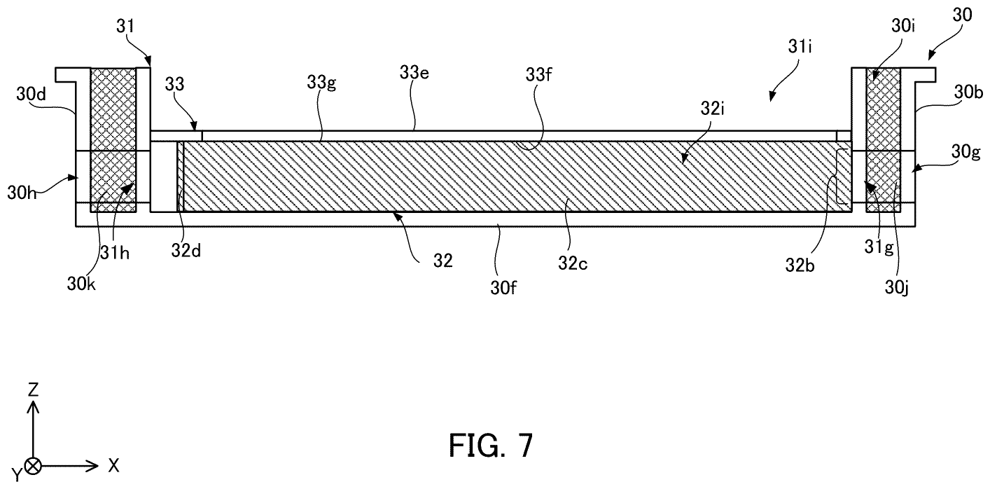

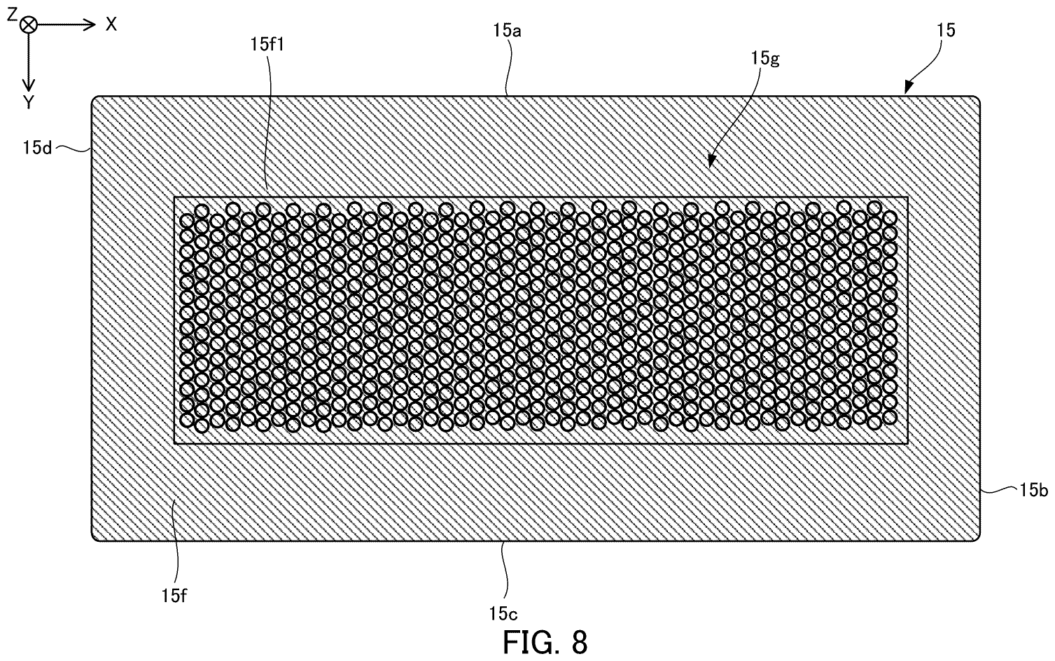

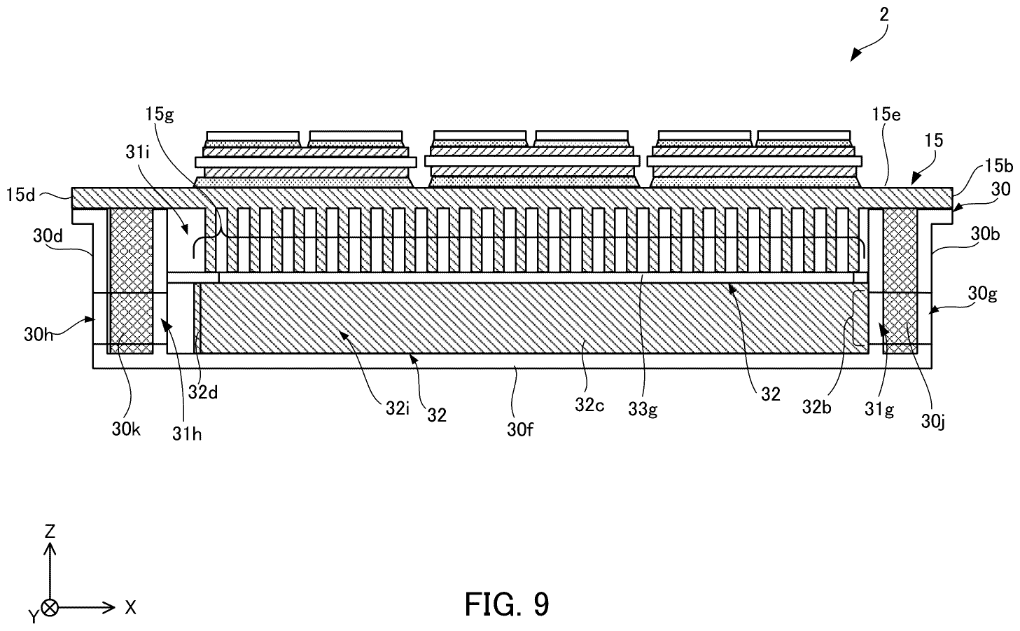

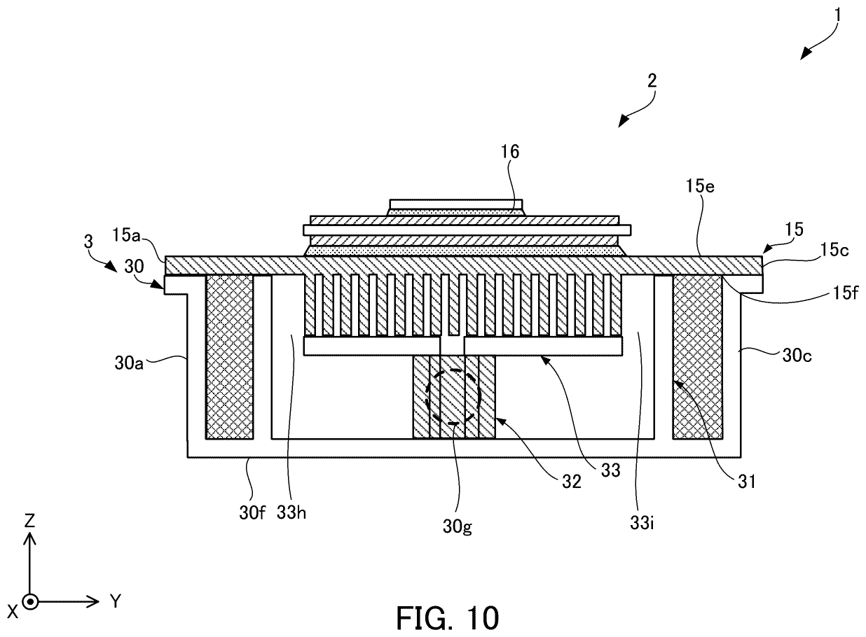

Next described is the cooling device 3, with reference to FIGS. 3 to 10. FIG. 3 is an exploded perspective view of a cooling device of the first embodiment. FIG. 4 is a plan view of the cooling device (excluding a guide plate) of the first embodiment. FIG. 5 is a cross-sectional view of the cooling device (excluding the guide plate) of the first embodiment. FIG. 6 is another plan view of the cooling device of the first embodiment. FIG. 7 is another cross-sectional view of the cooling device of the first embodiment. FIG. 8 is a back view of a heat dissipation plate of the first embodiment. FIG. 9 is a first cross-sectional view of a semiconductor device of the first embodiment. FIG. 10 is a second cross-sectional view of the semiconductor device of the first embodiment.

Note that the cross-sectional view of FIG. 5 is taken along dashed-dotted line Y-Y of FIG. 4. The cross-sectional view of FIG. 7 is taken along dashed-dotted line Y-Y of FIG. 6. The cross-sectional view of FIG. 9 is taken along dashed-dotted line Y-Y of FIG. 1. The cross-sectional view of FIG. 10 is taken along dashed-dotted lines X-X of FIGS. 1 and 2.

The cooling device 3 includes the aforementioned chassis 30, a guide part 32 included in the chassis 30, and a guide plate 33 provided on the guide part 32, as illustrated in FIG. 3. As described above, the chassis 30 includes the bottom plate 30f, the long lateral wall 30a, the short lateral wall 30b, the long lateral wall 30c, and the short lateral wall 30d, by which a housing area 30i is surrounded.

The chassis 30 includes a pool part 31 within the housing area 30i, as illustrated in FIGS. 4 and 5. The pool part 31 is provided within the housing area 30i, and has a long lateral wall 31a (long lateral face), a short lateral wall 31b (short lateral face), a long lateral wall 31c (long lateral face), and a short lateral wall 31d (short lateral face) individually formed on the bottom plate 30f (bottom surface). The long lateral wall 31a, the short lateral wall 31b, the long lateral wall 31c, and the short lateral wall 31d are disposed on the bottom plate 30f to form a rectangular shape in plan view, and define a pool area (pool space) 31i. The connection portions between the long lateral wall 31a, the short lateral wall 31b, the long lateral wall 31c, and the short lateral wall 31d may have rounded surfaces. Similarly, the connection portions of the long lateral wall 31a, the short lateral wall 31b, the long lateral wall 31c, and the short lateral wall 31d to the bottom plate 30f may also have rounded surfaces. Thus, provision of the rounded surfaces prevents the refrigerant flowing through the pool part 31 from stagnating at each corner of the pool part 31 and therefore facilitates smooth flow of the refrigerant, as described below.

The long lateral wall 31a, the short lateral wall 31b, the long lateral wall 31c, and the short lateral wall 31d of the pool part 31 oppose the long lateral wall 30a, the short lateral wall 30b, the long lateral wall 30c, and the short lateral wall 30d, respectively, of the chassis 30. In plan view, the pool area 31i is located, within the housing area 30i, at the center in each of the ±X direction and the ±Y direction. The long lateral wall 31a, the short lateral wall 31b, the long lateral wall 31c, and the short lateral wall 31d of the pool part 31 are the same in height. The heights of the long lateral wall 31a, the short lateral wall 31b, the long lateral wall 31c, and the short lateral wall 31d of the pool part 31 are equal to those of the long lateral wall 30a, the short lateral wall 30b, the long lateral wall 30c, and the short lateral wall 30d of the chassis 30.

Note that the area of the chassis 30 outside the pool area 31i but inside the housing area 30i may be sealed with a sealing member. Alternatively, the entire chassis 30 may be configured in a block shape using a sealing member, and a space corresponding to the pool area 31i may be opened up inside the chassis 30.

An inlet 31g and an outlet 31h are formed on the short lateral walls 31b and 31d, respectively, of the pool part 31. The inlet 31g and the outlet 31h communicate with a guide area (guide space) 32i and the pool area 31i, respectively, to be described later. The inlet 31g and the outlet 31h are arranged in a straight line in the ±X direction with respect to the inlet 30g and the outlet 30h, respectively, of the chassis 30. That is, the inlets 30g and 31g oppose one another while the outlets 30h and 31h oppose one another.

The inlets 30g and 31g and the outlets 30h and 31h above may have, for example, a circular shape. The inlets 30g and 31g and the outlets 30h and 31h may have the same diameter. The diameter of each of the inlets 30g and 31g and the outlets 30h and 31h may be, for example, 20% or more and 70% or less of the width of each of the short lateral walls 31b and 31d of the pool part 31 in the ±Y direction.

The inlets 30g and 31g and the outlets 30h and 31h are positioned, in the #Z direction, at the center of the height (in the ±Z direction) of the guide area 32i to be described later. Therefore, the inlets 30g and 31g and the outlets 30h and 31h are formed on the short lateral walls 30b and 30d of the chassis 30 and the short lateral walls 31b and 31d of the pool part 31 so as to correspond to the above positions.

In addition, the inlets 30g and 31g are connected by an inflow path 30j. Similarly, the outlets 30h and 31h are connected by an outflow path 30k. The inflow path 30j and the outflow path 30k also form a straight line. The inflow path 30j and the outflow path 30k may have a cylindrical shape, whose entire inner surface may be substantially flat with no unevenness.

Note that the locations where the outlets 30h and 31h are formed are not limited to the short lateral walls 30d and 31d. For example, the outlets 30h and 31h may be formed, within the pool area 31i, at a position in the bottom plate 30f, closer to the tip side (in the −X direction) than a tip wall 32d of the guide part 32, to be described later. In this case, the outflow path 30k penetrates the bottom plate 30f in the ±Z direction. Alternatively, the outlet 31h may be formed on the short lateral wall 31d so as to oppose the inlet 31g, and the outlet 30h may be formed in the bottom plate 30f outside the pool area 31i but within the housing area 30i. In this case, the outflow path 30k may connect the outlets 30h and 31h within the housing area 30i. Furthermore, the locations where the inlets 30g and 31g are formed are not limited to the short lateral walls 30b and 31b. For example, the inlets 30g and 31g may be formed, within the guide area 32i to be described later, at a position in the bottom plate 30f closer to the short lateral wall 31b. In this case, the inflow path 30j penetrates the bottom plate 30f in the #Z direction. Alternatively, the inlet 31g may be formed in the short lateral wall 31b so as to oppose the outlet 31h, and the inlet 30g may be formed in the bottom plate 30f outside the pool area 31i but within the housing area 30i. In this case, the inflow path 30j may connect the inlets 30g and 31g within the housing area 30i.

Note that the guide part 32 is provided on the bottom plate 30f within the pool area 31i of the pool part 31, as illustrated in FIGS. 3 to 5. The guide part 32 has a guide wall 32a (first guide wall), the tip wall 32d, and a guide wall 32c (second guide wall) integrally connected to each other, and includes a first end and a second end. The first end is included in the guide wall 32a and connected to the short lateral wall 31b of the pool part 31. The second end is included in the guide wall 32c and connected to the short lateral wall 31b of the pool part 31. The lower ends (the −Z direction) of the guide wall 32a, the tip wall 32d, and the guide wall 32c are connected to the bottom plate 30f. The connection portions between the guide wall 32a, the tip wall 32d, and the guide wall 32c may have rounded surfaces. Similarly, the connection portions of the guide wall 32a, the tip wall 32d, and the guide wall 32c to the bottom plate 30f may also have rounded surfaces. Thus, provision of the rounded surfaces prevents the refrigerant flowing through the guide part 32 from stagnating at each corner of the guide part 32 and therefore facilitates smooth flow of the refrigerant, as described below.

The guide wall 32a, the tip wall 32d, and the guide wall 32c are the same in height (in the ±Z direction). The heights of the guide wall 32a, the tip wall 32d, and the guide wall 32c (in the ±Z direction) may be lower than those of the chassis 30 and the pool part 31, and may be, for example, about 50% of the heights of the chassis 30 and the pool part 31. In addition, the inner surfaces of the guide wall 32a, the tip wall 32d, and the guide wall 32c may be substantially flat with no unevenness.

A first end of the guide wall 32a is connected to the inside of the short lateral wall 31b included in the pool part 31. Here, the first end of the guide wall 32a is, in plan view, connected to the side of the inlet 31g on the short lateral wall 31b. The guide wall 32a extends from the first end toward the short lateral wall 31d. In this regard, as the guide wall 32a extends toward the short lateral wall 31d, it passes through the center of the short lateral walls 31b and 31d in plan view and is inclined (to move closer) toward a center line (in FIG. 4, dashed-dotted line Y-Y corresponds to the center line) parallel to the long lateral walls 31a and 31c.

A second end of the guide wall 32c is also connected to the inside of the short lateral wall 31b of the pool part 31. Here, the second end of the guide wall 32c is connected to a position on the short lateral wall 31b, on the opposite side of the inlet 31g from the first end of the guide wall 32a. That is, the second end of the guide wall 32c is connected, within the side of the short lateral wall 31b, a position opposite to the first end of the guide wall 32a across the inlet 31g. The guide wall 32c extends from the second end toward the short lateral wall 31d. In this regard, the guide wall 32c is inclined (to move closer) toward the center line (in FIG. 4, dashed-dotted line Y-Y corresponds to the center line) as it extends toward the short lateral wall 31d.

The tip wall 32d is connected to the tips (in the −X direction) of the guide walls 32a and 32c. The tip wall 32d opposes the short lateral wall 31d of the pool part 31. That is, the tip wall 32d is parallel to the short lateral wall 31d of the pool part 31. Further, the tip wall 32d is disposed with a gap from the short lateral wall 31d of the pool part 31. In plan view, the tip wall 32d is located, in the ±Y direction, at the center of each of the short lateral walls 31b and 31d of the pool part 31. The width of the tip wall 32d in plan view (in the ±Y direction) is smaller than the length, on the short lateral wall 31b, between the position to which the first end of the guide wall 32a is connected and the position to which the second end of the guide wall 32c is connected. Further, the width of the tip wall 32d in plan view (in the ±Y direction) is smaller than the diameter of the inlet 31g.

In addition, an inlet 32b is formed between the first end of the guide wall 32a and the second end of the guide wall 32c of the guide part 32. The width (in the ±Y direction) of the inlet 32b may be approximately the same as the diameter of the inlet 31g but is larger than that of the inlet 31g.

Providing the guide part 32 in the pool part 31 in the above-described manner creates the guide area 32i surrounded by the guide part 32 and the short lateral wall 31b. In addition, the guide part 32 defines the guide area 32i and the pool area 31i outside the guide area 32i. Note that the inlet 32b of the guide part 32 communicates with the guide area 32i. Therefore, a passage is formed from the inlet 30g to the guide area 32i, passing through the inflow path 30j and the inlets 31g and 32b.

The guide plate 33 has a flat plate shape, and includes a front surface 33e being rectangular in plan view; a rear surface 33f opposite to the front surface 33e; and a long lateral face 33a, a short lateral face 33b, a long lateral face 33c, and a short lateral face 33d surrounding in order all four sides of the front surface 33e and the rear surface 33f, as illustrated in FIGS. 3, 6, and 7. The guide plate 33 is disposed on the guide part 32 within the pool part 31. The lengths of the long lateral faces 33a and 33c of the guide plate 33 in the ±X direction are the same as the length of the pool part 31 in the same direction. The widths of the short lateral faces 33b and 33d of the guide plate 33 in the ±Y direction are less than the width of the pool part 31 in the same direction. When the guide plate 33 with the above configuration is placed on the guide part 32, first and second collection gaps 33h and 33i are formed, in plan view, between the long lateral faces 33a and 33c of the guide plate 33 and the long lateral walls 31a and 31c, respectively, of the pool part 31. Note that the widths of the first and second collection gaps 33h and 331 in the ±Y direction may be, for example, 1 mm.

In addition, the guide plate 33 is provided with a guide slit 33g (slit) that penetrates the guide plate 33 from the front surface 33e to the rear surface 33f. The guide slit 33g is formed on the guide plate 33 in such a manner that, when the guide plate 33 is placed on the guide part 32, the guide slit 33g overlaps the guide area 32i in plan view and extends in a straight line from the inlet 32b toward the tip wall 32d to just before the tip wall 32d. In addition, the guide slit 33g is formed on the guide plate 33 in such a manner as to be laid on a center line (corresponding to dashed-dotted line Y-Y of FIG. 6) passing through the individual centers of the inlet 32b and the tip wall 32d of the guide part 32 in plan view when the guide plate 33 is placed on the guide part 32. The width (in the ±Y direction) of the guide slit 33g is, in plan view, ⅙ or more and ⅕ or less of the width of the inlet 32b in the same direction. In the case of the first embodiment, the width of the guide slit 33g may be, for example, 2 mm or more and 4 mm or less, and may be specifically 2 mm.

The guide area 32i surrounded by the above-described guide part 32, bottom plate 30f, and guide plate 33 becomes smaller as it moves away from the inlet 32b when viewed in the inflow direction from the inlet 32b of the guide part 32 toward the guide area 32i. The guide part 32 and the bottom plate 30f are formed so as to provide the guide area 32i with this configuration.

Next described is the heat dissipation plate 15, to the rear surface 15f of which the cooling device 3 is joined. The heat dissipation plate 15 includes the front surface 15e having a rectangular shape in plan view, the rear surface 15f, the long lateral face 15a, the short lateral face 15b, the long lateral face 15c, and the short lateral face 15d, as described above. The heat dissipation plate 15 has multiple fins 15g formed in a region of the rear surface 15f (a cooling area 15f1) corresponding to the unit area 15e1 of the front surface 15e, as illustrated in FIG. 8. Each of the fins 15g has a columnar shape. The columnar shape may be a cylindrical or polygonal column. The multiple fins 15g are formed perpendicular to the rear surface 15f of the heat dissipation plate 15.

The heat dissipation plate 15 with the above configuration is placed in the chassis 30, with the semiconductor unit 2 disposed on the front surface 15e, as illustrated in FIGS. 9 and 10. At this time, the rear surface 15f of the heat dissipation plate 15 is placed on the pool part 31, and the multiple fins 15g of the heat dissipation plate 15 are accommodated in the pool area 31i over the guide plate 33 within the pool part 31. That is, the multiple fins 15g of the heat dissipation plate 15 are surrounded by the guide plate 33 on the back side (in the −Z direction), and also surrounded on all sides by the long lateral wall 31a, the short lateral wall 31b, the long lateral wall 31c, and the short lateral wall 31d in this order.

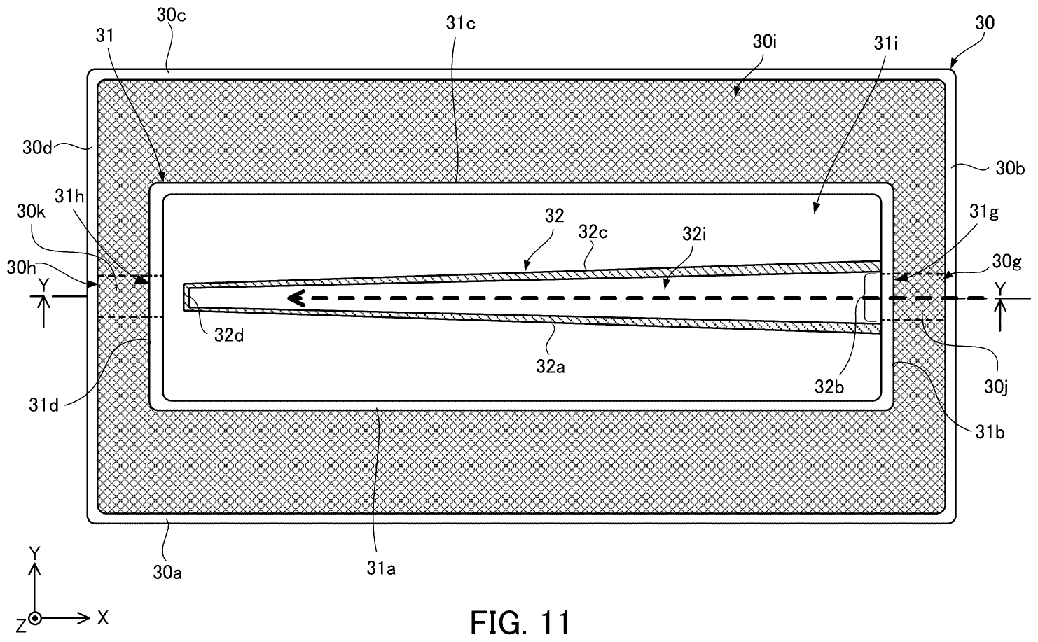

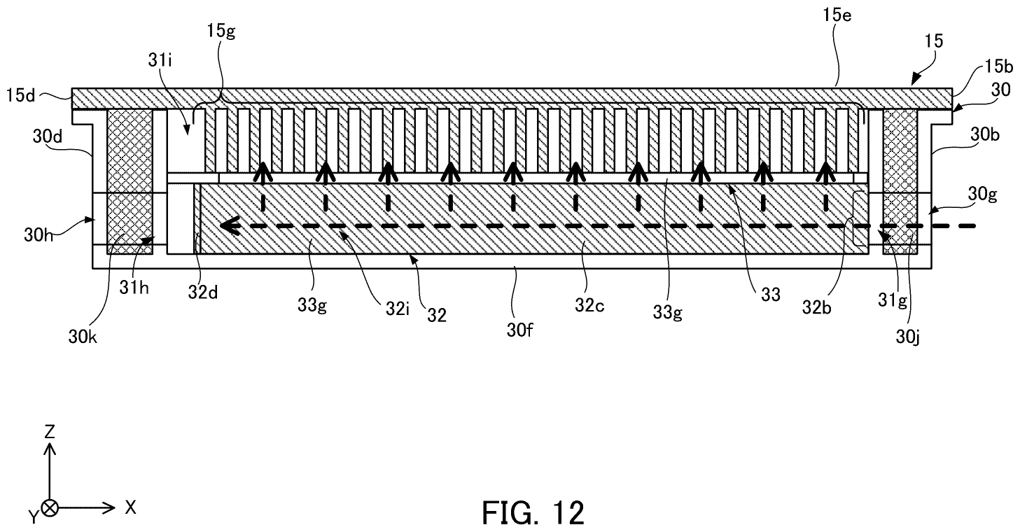

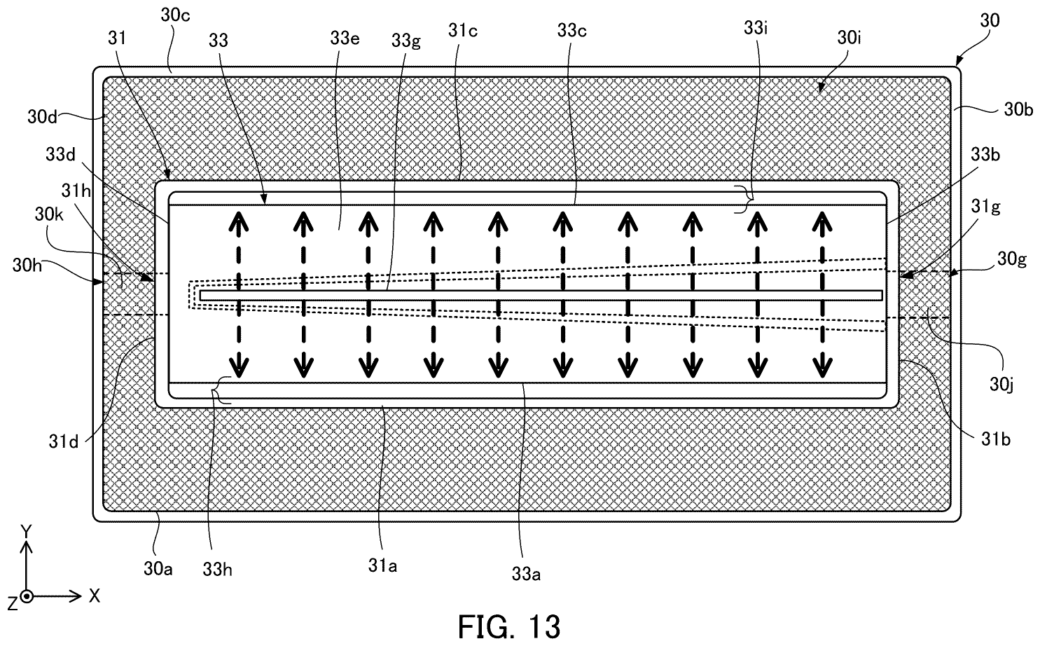

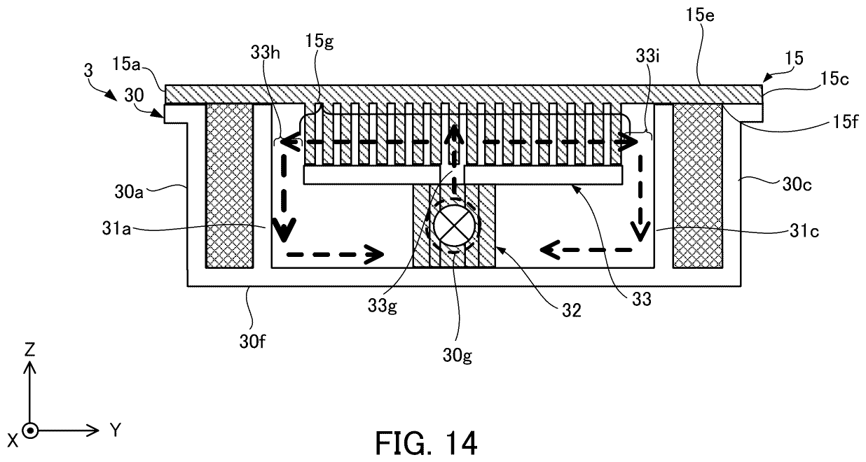

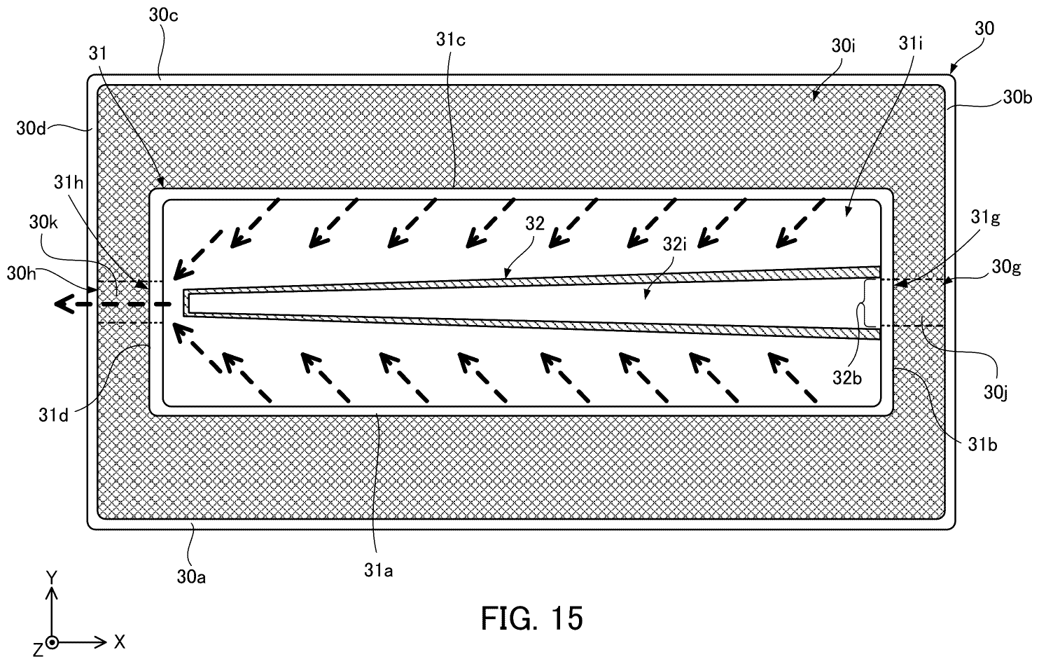

Next described is the flow of the refrigerant in the cooling device 3, with reference to FIGS. 11 to 15. FIG. 11 is a first plan view illustrating the flow of the refrigerant in the cooling device of the first embodiment. FIG. 12 is a first cross-sectional view illustrating the flow of the refrigerant in the cooling device of the first embodiment. FIG. 13 is a second plan view illustrating the flow of the refrigerant in the cooling device of the first embodiment. FIG. 14 is a second cross-sectional view illustrating the flow of the refrigerant in the cooling device of the first embodiment. FIG. 15 is a third plan view illustrating the flow of the refrigerant in the cooling device of the first embodiment.

Note that in the above diagrams, the flow of the refrigerant is indicated by broken arrows. In addition, illustration of the heat dissipation plate 15 and the guide plate 33 is omitted from the diagrams as appropriate for explanation of the flow of the refrigerant. Note that the cross-sectional view of FIG. 12 is taken along dashed-dotted line Y-Y of FIG. 11. FIG. 14 is a perspective side view of FIG. 13, viewed in the −X direction.

First, the refrigerant is introduced from the inlet 30g of the cooling device 3 using a pump. The refrigerant flowing in from the inlet 30g passes through the inflow path 30j, enters the guide area 32i from the inlets 31g and 32b, and travels straight in the −X direction, as illustrated in FIGS. 11 and 12. When the refrigerant fills the guide area 32i to some extent, the refrigerant flows out from the guide slit 33g of the guide plate 33 to the outside of the guide plate 33.

The guide area 32i becomes smaller as it moves away from the inlet 32b when viewed in the inflow direction from the inlet 32b toward the guide area 32i. This configuration allows the pressure difference in the refrigerant having entered the guide area 32i between the tip wall 32d side and the inlet 32b side to be reduced, which facilitates the refrigerant to flow out also from a part of the guide slit 33g near the inlet 32b. Therefore, the refrigerant having flowed into the guide area 32i flows out substantially uniformly from the entire guide slit 33g.

The refrigerant having flowed into the pool area 31i over the guide plate 33 from the guide slit 33g passes through the multiple fins 15g toward the first and second collection gaps 33h and 33i provided along the long lateral faces 33a and 33c of the guide plate 33, as illustrated in FIG. 13. The refrigerant flowing through the fins 15g receives heat conducted from the semiconductor unit 2 through the heat dissipation plate 15 and the fins 15g.

The refrigerant having flowed from the guide slit 33g toward the first and second collection gap 33h and 33i flows from the first and second collection gaps 33h and 33i into the pool area 31i, which is surrounded by the guide plate 33, the long lateral wall 31a, the short lateral wall 31b, the long lateral wall 31c, and the short lateral wall 31d, as illustrated in FIG. 14.

The refrigerant having flowed into the pool area 31i below the guide plate 33 flows through the pool area 31i outside the guide area 32i toward the outlet 30h, and then flows out from the outlet 30h, as illustrated in FIG. 15.

The radiator receives the refrigerant flowing out from the cooling device 3 in the above-described manner, and dissipates heat contained in the refrigerant to the outside. The pump causes the refrigerant after heat dissipation to flow into the cooling device 3 again through the inlet 30g.

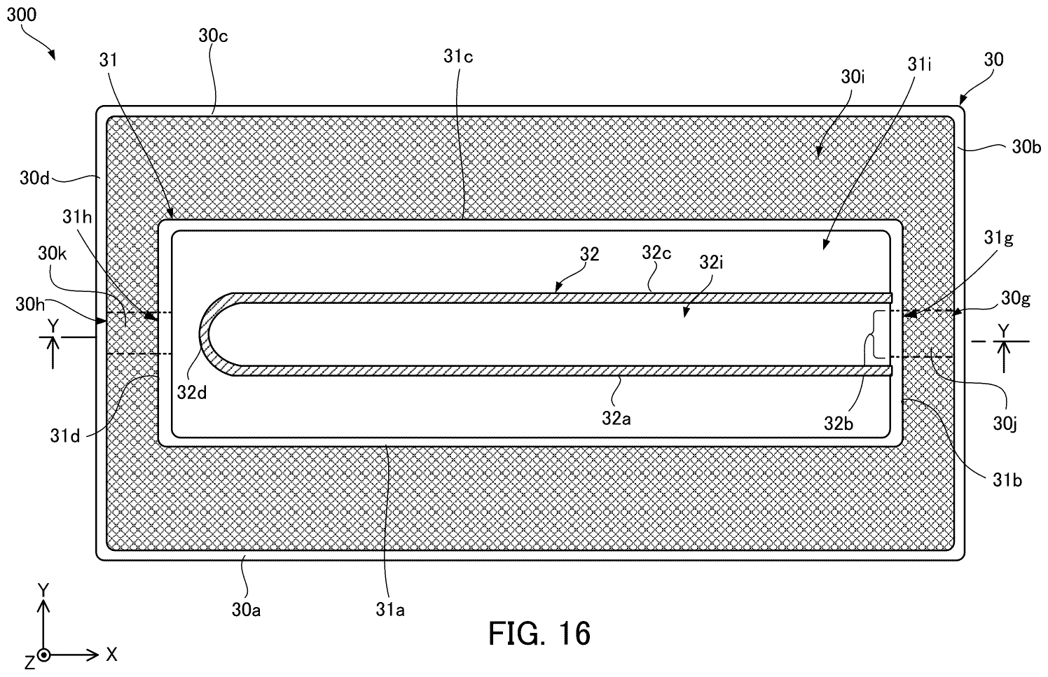

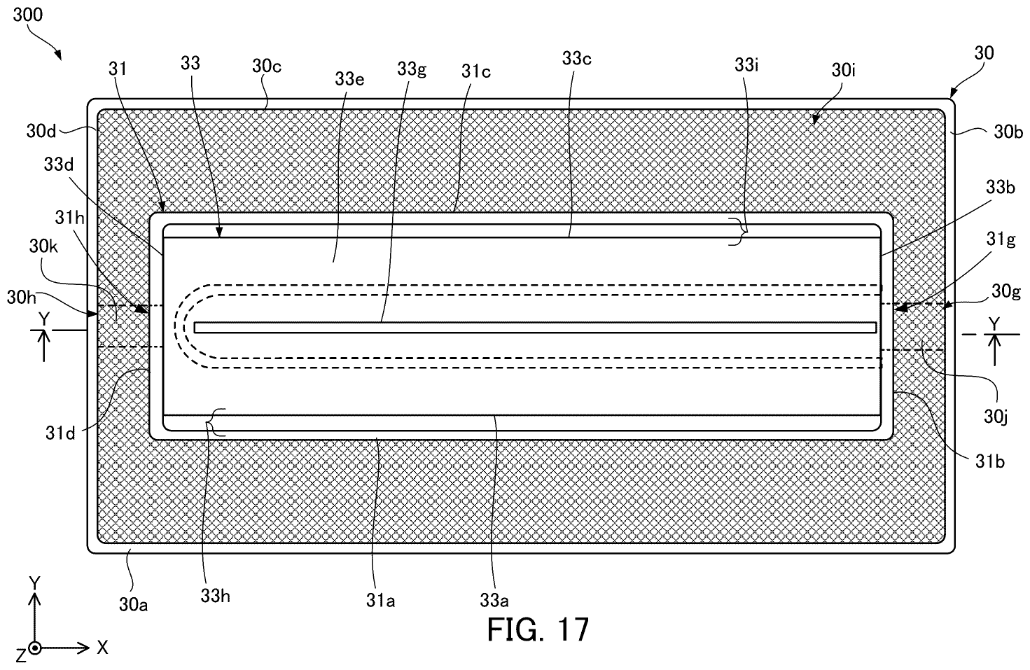

Here, a cooling device of a reference example is explained using FIGS. 16 and 17. FIG. 16 is a plan view of the cooling device (excluding a guide plate) of the reference example. FIG. 17 is another plan view of the cooling device of the reference example. Note that the plan view of FIG. 16 depicts a cooling device 300 without the guide plate 33.

The cooling device 300 of the reference example differs from the cooling device 3 of the first embodiment in the guide part 32. In the guide part 32 of the cooling device 300, the guide wall 32a, the tip wall 32d, and the guide wall 32c are integrally connected to each other. Note that, in the reference example, the guide walls 32a and 32c are provided parallel to the long lateral walls 31a and 31c of the pool part 31, as illustrated in FIG. 16. In addition, in the reference example, the tip wall 32d connects the tip sides (in the −X direction) of these guide walls 32a and 32c. The tip wall 32d is arc-shaped, bulging toward the short lateral wall 31d.

Similarly to the first embodiment, when the guide plate 33 is placed on the guide part 32, the first and second collection gaps 33h and 33i are formed, in plan view, between the long lateral faces 33a and 33c of the guide plate 33 and the long lateral walls 31a and 31c of the pool part 31. In addition, as illustrated in FIG. 17, the guide slit 33g is formed on the guide plate 33 in such a manner as to be laid on a center line (corresponding to dashed-dotted line Y-Y of FIG. 17) passing through the individual centers of the inlet 32b and the tip wall 32d of the guide part 32 in plan view when the guide plate 33 is placed on the guide part 32. In this reference example, the guide area 32i surrounded by the bottom plate 30f, the guide part 32, and the guide plate 33 has a substantially cubic shape.

When the refrigerant flows s into the cooling device 300 with the above configuration from the inlet 30g, it passes through the inflow path 30j and enters the guide area 32i from the inlets 31g and 32b, as in the first embodiment. When filling the guide area 32i to some extent, the refrigerant starts flowing out from the guide slit 33g of the guide plate 33 to the outside of the guide plate 33.

At this time, if the width of the guide slit 33g is narrow (for example, about 1 mm), the refrigerant is able to uniformly flow out from the entire guide slit 33g. However, the guide slit 33g being thin leads to increased pressure drop in the refrigerant. This in turn results in, for example, an increased cost of driving the pump.

On the other hand, when the width of the guide slit 33g is wide (for example, about 2 mm), the refrigerant fails to uniformly flow out from the entire guide slit 33g.

In the reference example, the guide area 32i hardly changes even if it moves away from the inlet 32b when viewed in the inflow direction from the inlet 31g (the inlet 32b) of the pool part 31 to the guide area 32i. The pressure of the refrigerant flowing into the guide area 32i increases as it approaches the tip wall 32d of the guide area 32i. The flow velocity of the refrigerant is reduced, in plan view, on the inlet 32b side of the guide slit 33g than on the tip wall 32d side.

Therefore, the flow velocity of the refrigerant flowing out from the guide slit 33g is higher on the tip wall 32d side than on the inlet 32b side. As a result, heat dissipation performance on the front surface 15e of the heat dissipation plate 15 varies depending on the position. That is, the heat dissipation of the front surface 15e of the heat dissipation plate 15 is lower on the inlet 30g (the inlet 32b) side compared to the outlet 30h (the tip wall 32d) side. This causes variations in the heat dissipation performance for the semiconductor chips 14 included in the semiconductor unit 2 on the front surface 15e of the heat dissipation plate 15. The variations in the heat dissipation performance for the semiconductor unit 2 lead to reduced reliability of the semiconductor device 1. Details of the heat dissipation performance is described later.

In view of the above problem, the semiconductor device 1 of the first embodiment includes the semiconductor chips 14, the heat dissipation plate 15, and the cooling device 3. The heat dissipation plate 15 includes the front surface 15e having the unit area 15e1 on which the semiconductor chips 14 are arranged; the rear surface 15f with the cooling area 15f1 corresponding to the unit area 15e1; and the multiple fins 15g installed in the cooling area 15f1.

The cooling device 3 is provided on the rear surface 15f of the heat dissipation plate 15, and includes the pool part 31, the guide part 32, and the guide plate 33. The pool part 31 has the pool area 31i surrounded and defined, in plan view, by the rectangular bottom plate 30f, the paired long lateral walls 31a and 31c, and the paired short lateral walls 31b and 31d. The pool part 31 is also provided with the inlet 31g on one of the short lateral walls 31b and 31d (in this example, the short lateral wall 31b).

The guide part 32 is formed on the bottom plate 30f in such a manner that the first end thereof is connected to the inner side of the short lateral wall 31b while the second end is connected to a position on the short lateral wall 31b, opposite to the first end across the inlet 31g so as to separate the guide area 32i communicating with the inlet 31g from the pool area 31i outside the guide area 32i.

The guide plate 33 is disposed on the guide part 32 with the first and second collection gaps 33h and 33i from the long lateral walls 31a and 31c, respectively, within the pool area 31i, and has a flat plate shape with the guide slit 33g, which extends from the short lateral wall 31b toward the short lateral wall 31d within an area overlapping the guide area 32i.

When the cooling device 3 is attached to the rear surface 15f of the heat dissipation plate 15, the multiple fins 15g are housed in the pool area 31i over the guide plate 33. In the cooling device 3 with the above configuration, the guide part 32 is further configured in such a manner that the guide area 32i thereof becomes smaller as it moves away from the inlet 31g of the pool part 31 when viewed in the inflow direction from the inlet 31g toward the guide area 32i.

The above configuration allows the pressure difference in the refrigerant having entered the guide area 32i between the tip wall 32d side and the inlet 32b side to be reduced, which facilitates the refrigerant to flow out also from the part of the guide slit 33g near the inlet 32b. Therefore, the refrigerant having flowed into the guide area 32i flows out substantially uniformly from the entire guide slit 33g. This in turn reduces variations in the heat dissipation performance depending on the position on the front surface 15e of the heat dissipation plate 15, and thus uniformly cools the semiconductor unit 2. The reduced pressure drop enables a reduction in the cost of driving the pump and also reduces the loss of reliability of the semiconductor device 1.

### (b) Second Embodiment

The guide part 32 needs to be configured in such a manner that the guide area 32i surrounded by the guide part 32, the bottom plate 30f, and the guide plate 33 becomes smaller as it moves away from the inlet 31g of the pool part 31 when viewed in the inflow direction from the inlet 31g toward the guide area 32i. In the first embodiment, the guide walls 32a and 32c of the guide part 32 are inclined so as to come closer to a center line, which passes through the center of each of the short lateral walls 31b and 31d, as they move away from the short lateral wall 31b toward the short lateral wall 31d.

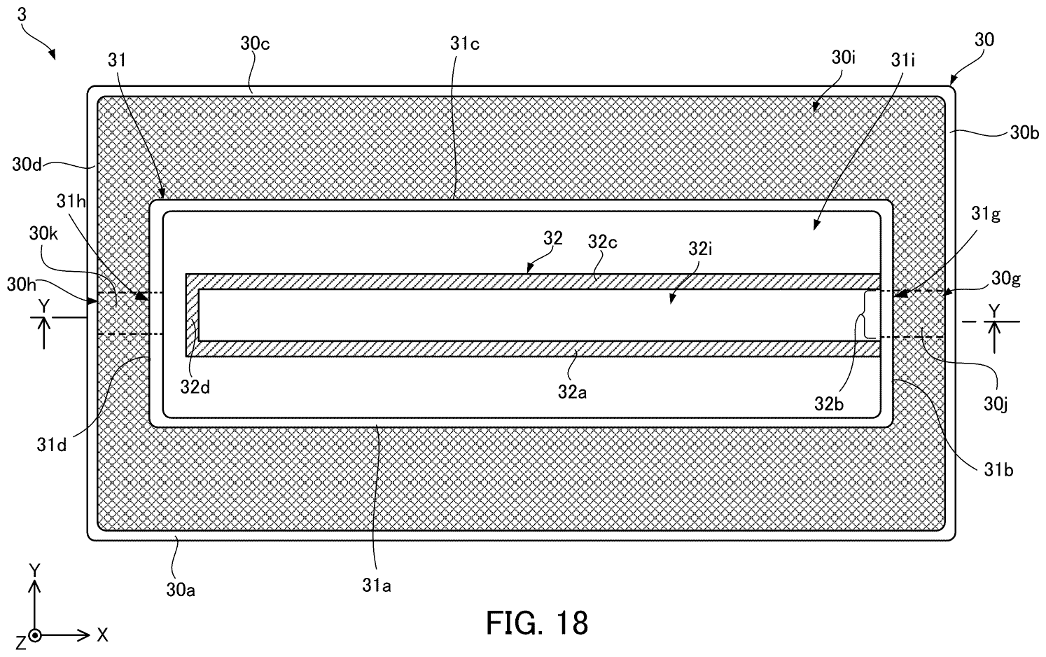

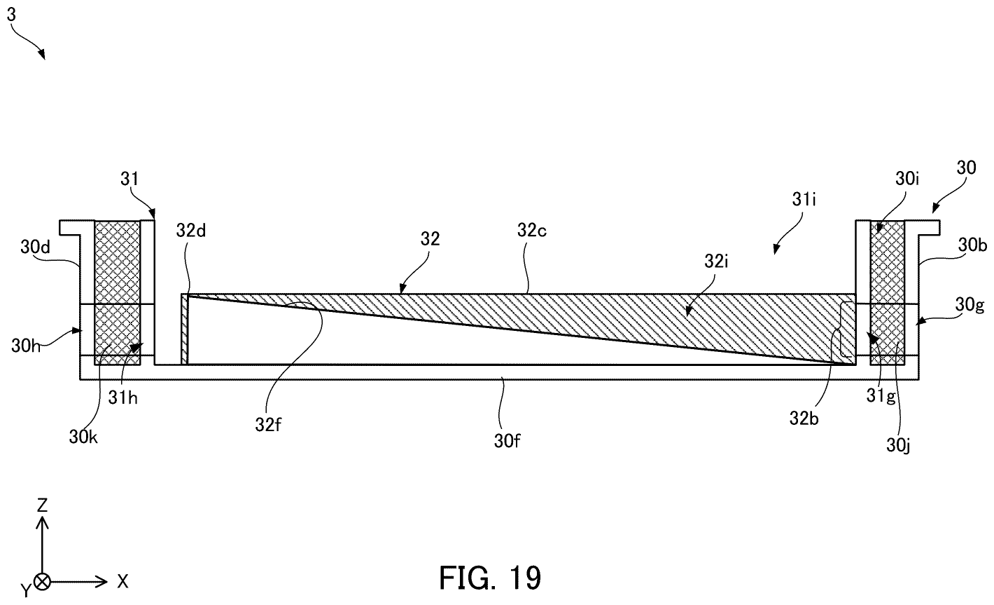

Next described is a cooling device according to a second embodiment, with reference to FIGS. 18 and 19. FIG. 18 is a plan view of a cooling device (excluding a guide plate) of the second embodiment. FIG. 19 is a cross-sectional view of the cooling device (excluding the guide plate) of the second embodiment. Note that the cross-sectional view of FIG. 19 is taken along dashed-dotted line Y-Y of FIG. 18.

The guide part 32 of the second embodiment has the guide wall 32a, the tip wall 32d, and the guide wall 32c integrally connected to each other, and includes the first end and the second end, as in the first embodiment. In addition, both the first and second ends are connected to the short lateral wall 31b across the inlet 31g, similarly to the first embodiment.

Note however that, according to the second embodiment, the guide walls 32a and 32c extend from the short lateral wall 31b toward the short lateral wall 31d, parallel to the long lateral as walls 31a and 31c, illustrated in FIG. 18. The tip wall 32d integrally connects the tips (in the −X direction) of the guide walls 32a and 32c. In FIG. 18, the connection portions between the tip wall 32d and the guide walls 32a and 32c form right angles. The connection portions may have R- or C-chamfered corners. In addition, the tip wall 32d may be arc-shaped, as illustrated in FIG. 16.

Furthermore, in the second embodiment, the guide part 32 is formed on the bottom plate 30f in such a manner that a bottom surface 32f surrounded by the guide part 32 is inclined upward (in the +Z direction) as it goes from the short lateral wall 31b toward the short lateral wall 31d.

Herewith, the guide area 32i surrounded by the guide part 32, the bottom surface 32f, and the guide plate 33 (not illustrated in FIGS. 18 and 19) becomes smaller as it moves away from the inlet 31g of the pool part 31 when viewed in the inflow direction from the inlet 31g toward the guide area 32i.

The guide part 32 forming the guide area 32i with the above configuration also allows the pressure difference in the refrigerant having entered the guide area 32i between the outlet 30h (the tip wall 32d) side and the inlet 32b side to be reduced, similarly to the first embodiment. This facilitates the refrigerant to flow out also from the part of the guide slit 33g near the inlet 32b. Therefore, the refrigerant having flowed into the guide area 32i flows out substantially uniformly from the entire guide slit 33g. This in turn reduces variations in the heat dissipation performance depending on the position on the front surface 15e of the heat dissipation plate 15, and thus uniformly cools the semiconductor unit 2. The reduced pressure drop enables a reduction in the cost of driving the pump and also reduces the loss of reliability of the semiconductor device 1.

### (c) Third Embodiment

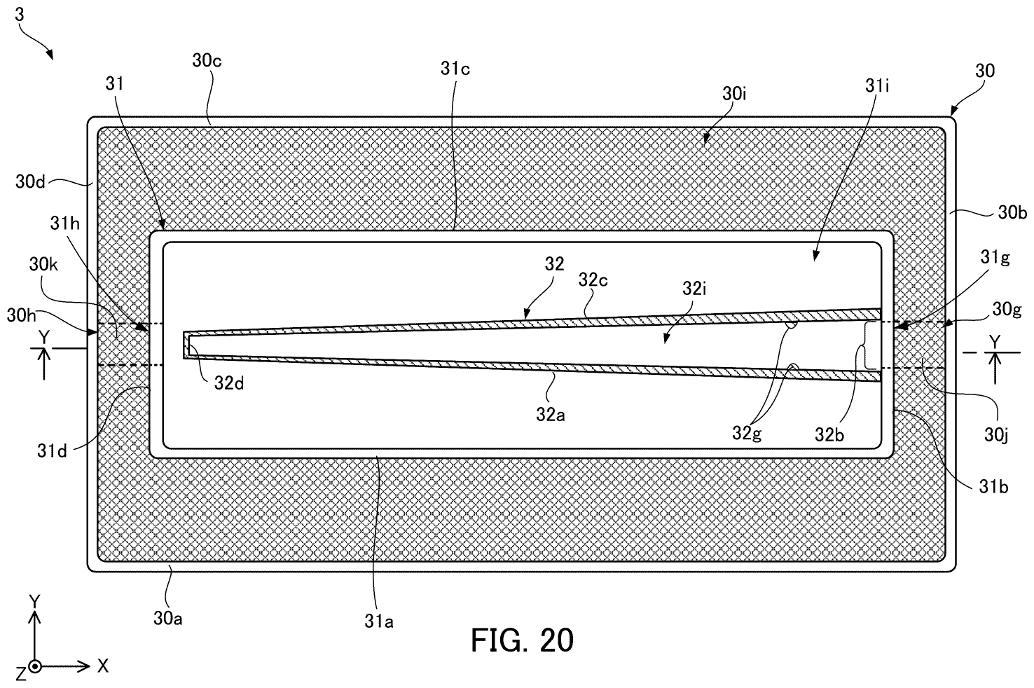

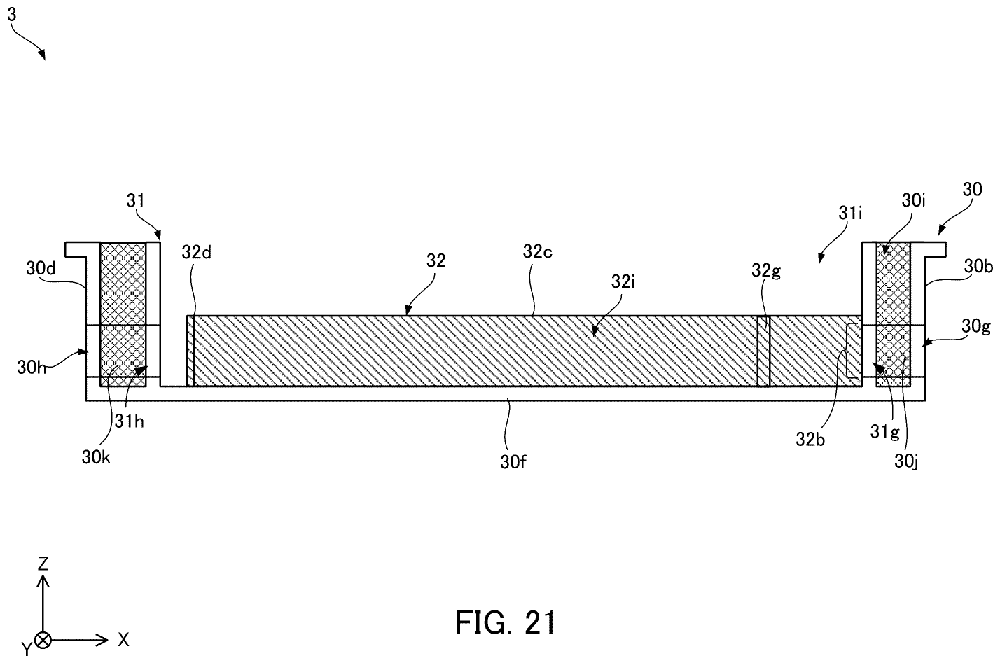

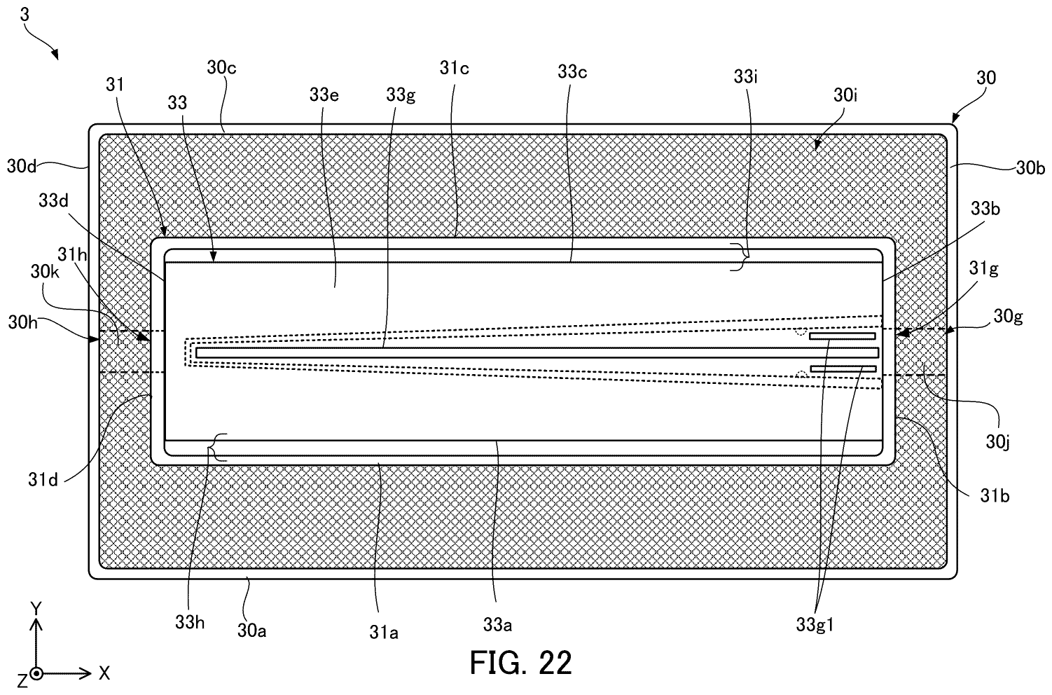

A cooling device of a third embodiment is explained using FIGS. 20 to 22. FIG. 20 is a plan view of a cooling device (excluding a guide plate) of the third embodiment. FIG. 21 is a cross-sectional view of the cooling device (excluding the guide plate) of the third embodiment. FIG. 22 is another plan view of the cooling device of the third embodiment. Note that the cross-sectional view of FIG. 21 is taken along dashed-dotted line Y-Y of FIG. 20.

The cooling device 3 of the third embodiment differs from the cooling device 3 of the first embodiment in having protrusions 32g, on the guide walls 32a and 32c included in the guide part 32, at positions opposing each other. The protrusions 32g are formed closer to the inlet 31g side in plan view.

These protrusions 32g may be formed within 30% of the length of the guide walls 32a and 32c from the inlet 31g. In addition, the protruding amount of the protrusions 32g into the guide area 32i may be such that the protrusions 32g do not obstruct the flow of the refrigerant, and the protrusions 32g are sufficient if they project even a little. In addition, the protrusions 32g may be rod-shaped in side view and are formed parallel to each other in the ±Z direction from the lower ends to the upper ends of the guide walls 32a and 32c, as illustrated in FIG. 21. The protrusions 32g may be inclined at an obtuse angle with respect to the bottom plate 30f. That is, the protrusions 32g may be inclined in such a manner that their upper ends are located closer to the outlet 31h (the tip wall 32d) side. The protrusions 32g may each have, for example, a semicircular shape, a triangular shape, or a quadrangular shape in plan view. The example of FIG. 20 depicts the protrusions 32g having a semicircular shape.

In addition, the guide plate 33 has sub-slits 33g1 formed on both sides (the long lateral face 33a and 33c sides) of the guide slit 33g, within the range sandwiched between the guide walls 32a and 32c in plan view, as illustrated in FIG. 22. The sub-slits 33g1 extend parallel to the guide slit 33g toward the short lateral wall 31d, from the short lateral wall 31b to the protrusions 32g. Further, the width of each sub-slit 33g1 in the ±Y direction may be the same as the width of the guide slit 33g in the same direction, and is, for example, 1 mm or more and 4 mm or less.

This case also allows the pressure difference in the refrigerant having entered the guide area 32i between the tip wall 32d side and the inlet 32b side to be reduced, as in the first embodiment, which facilitates s the refrigerant to flow out also from the part of the guide slit 33g near the inlet 32b. At this time, the protrusions 32g promote smooth flow of the refrigerant having entered the guide area 32i toward the guide plate 33. Further, the guide plate 33 has the sub-slits 33g1 formed, on both sides of the guide slit 33g, near the protrusions 32g. This allows the refrigerant having entered the guide area 32i to flow out substantially uniformly from the entire guide slit 33g and the sub-slits 33g1 even more reliably than in the first embodiment.

Note that the refrigerant separated by the protrusions 32g flows out from the sub-slits 33g1. Therefore, the sub-slits 33g1 formed on the guide plate 33 preferably extend, in plan view, from the inlet 31g to at least the protrusions 32g. The sub-slits 33g1 may extend beyond the protrusions 32g.

### (d) Fourth Embodiment

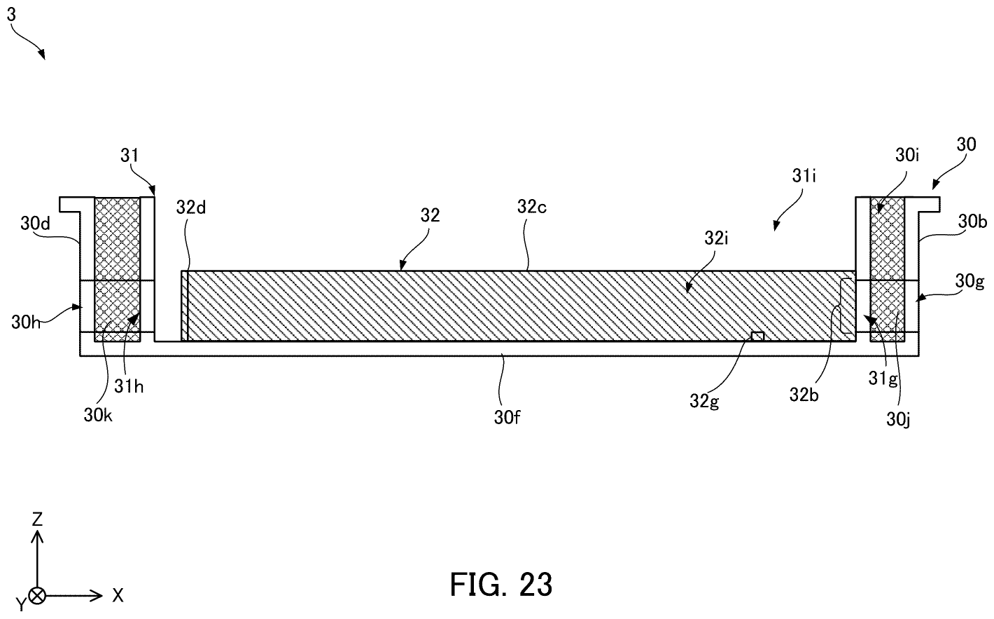

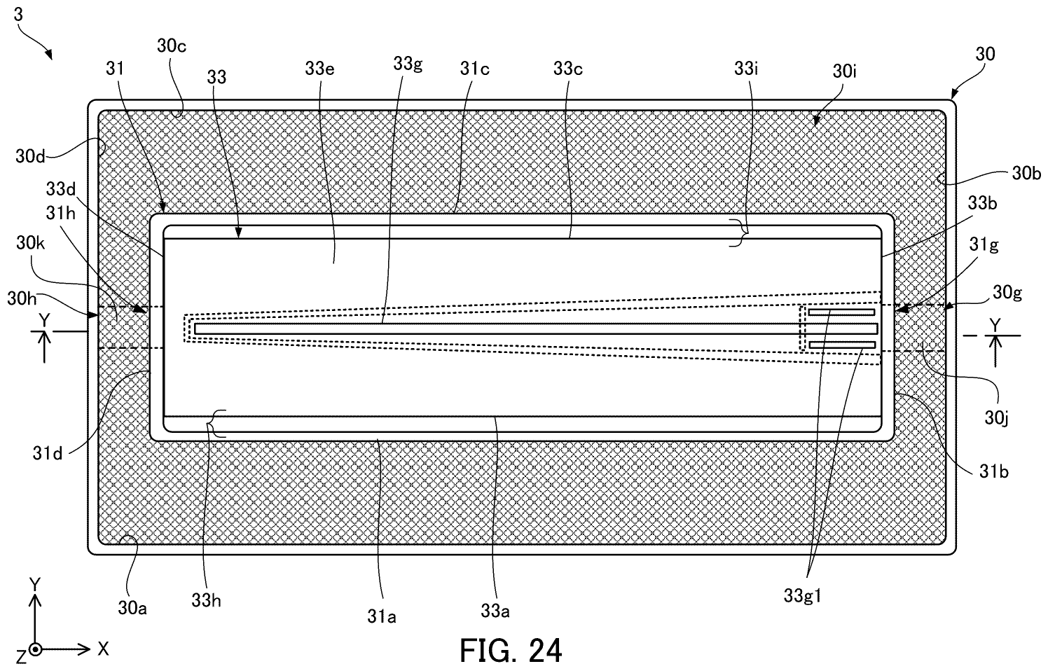

Next described is a fourth embodiment where a protrusion is formed on the bottom plate 30f of the third embodiment, with reference to FIGS. 23 and 24. FIG. 23 is a cross-sectional view of a cooling device (excluding a guide plate) of the fourth embodiment. FIG. 24 is a plan view of the cooling device of the fourth embodiment. Note that the cross-sectional view of FIG. 23 is taken along dashed-dotted line Y-Y of FIG. 24.

The cooling device 3 of the fourth embodiment differs from the cooling device 3 of the third embodiment in having the protrusion 32g not on each of the guide walls 32a and 32c, but on the bottom plate 30f. The protrusion 32g of the fourth embodiment is formed, on the bottom plate 30f, between the guide walls 32a and 32c in plan view in such a manner as to run parallel to the short lateral walls 31b and 31d. The protrusion 32g may be formed to connect the guide walls 32a and 32c in plan view.

In addition, the protruding amount of the protrusion 32g into the guide area 32i may be such that the protrusion 32g does not obstruct the flow of the refrigerant, and the protrusion 32g is sufficient if it projects even a little. Further, the protrusion 32g may have a columnar shape, such as a semicircular columnar shape, a quadrangular columnar shape, or a triangular columnar shape.

The sub-slits 33g1 of the guide plate 33 are also formed on both sides (the long lateral face 33a and 33c sides) of the guide slit 33g, within the range sandwiched between the guide walls 32a and 32c in plan view, as in the third embodiment. The sub-slits 33g1 extend parallel to the guide slit 33g toward the short lateral wall 31d, from the short lateral wall 31b to at least the protrusion 32g.

This case also allows the pressure difference in the refrigerant having entered the guide area 32i between the tip wall 32d side and the inlet 32b side to be reduced, as in the second embodiment, which facilitates the refrigerant to flow out also from the part of the guide slit 33g near the inlet 32b. Further, the guide plate 33 has the sub-slits 33g1 formed, on both sides of the guide slit 33g, near the protrusion 32g. This allows the refrigerant having entered the guide area 32i to flow out substantially uniformly from the entire guide slit 33g and the sub-slits 33g1 even more reliably than in the first embodiment.

Note that the protrusions 32g and the sub-slits 33g1 of the third and fourth embodiments are also applicable to the second embodiment. Further, the protrusions 32g of both the third and fourth embodiments may be provided together. That is, the paired protrusions 32g are formed, on the guide walls 32a and 32c of the guide part 32, at positions opposing each other, and another protrusion 32g is also formed on the bottom plate 30f. Note that these three protrusions 32g may be continuous. In this case, the refrigerant having entered the guide area 32i flows out substantially uniformly from the entire guide slit 33g and the sub-slits 33g1 even more reliably than in the third and fourth embodiments.

### (e) Fifth Embodiment

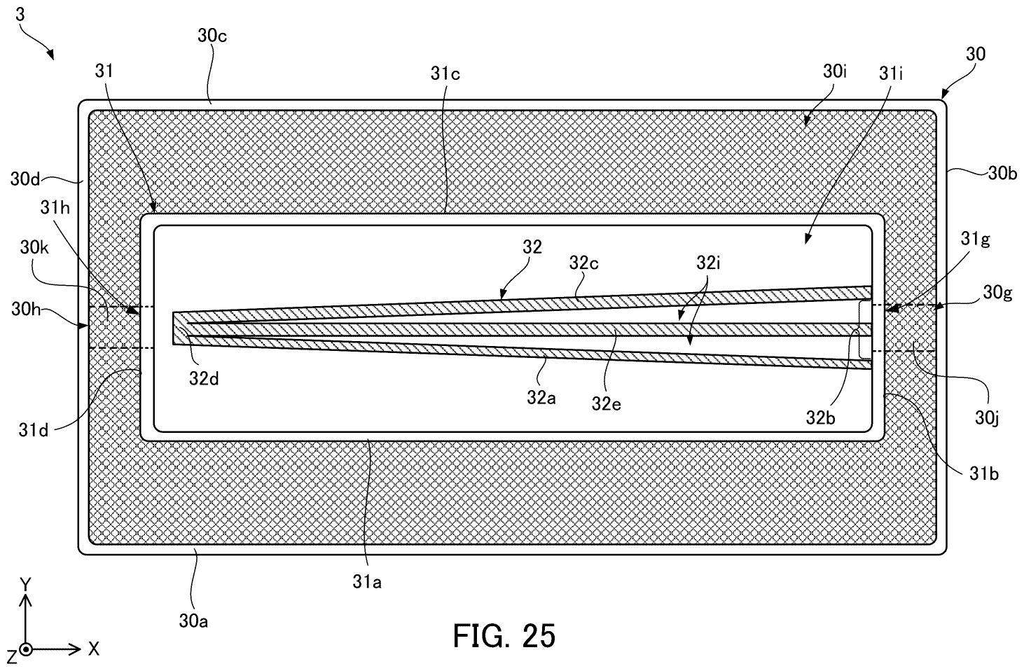

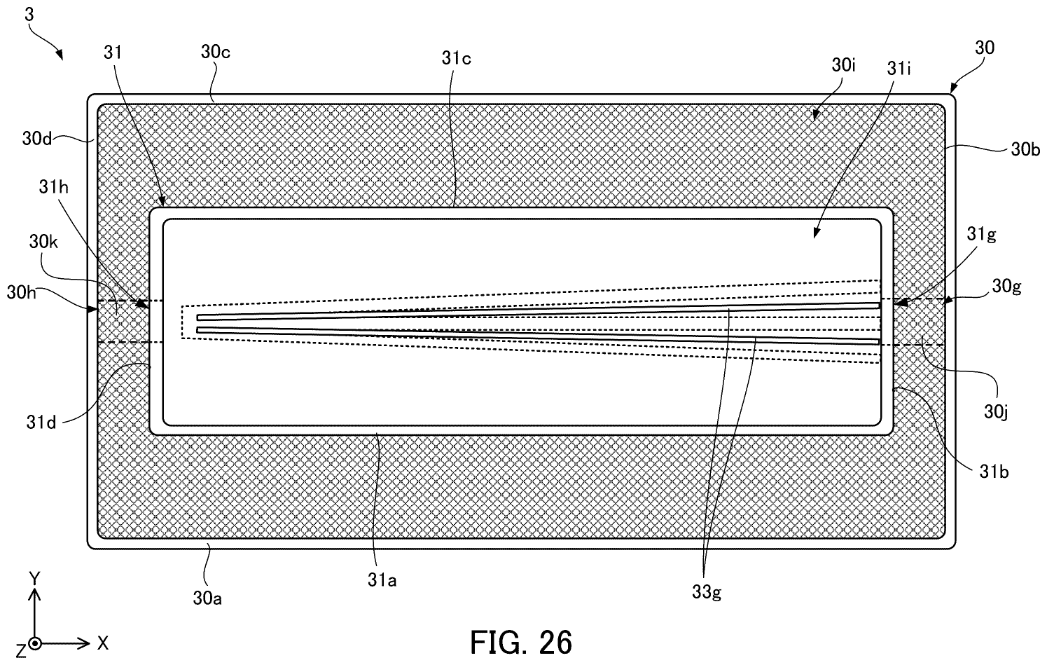

Next described is a fifth embodiment where the cooling device 3 of the first embodiment has the guide area 32i which is divided into two, with reference to FIGS. 25 and 26. FIG. 25 is a plan view of the cooling device (excluding a guide plate) of the fifth embodiment. FIG. 26 is another plan view of the cooling device of the fifth embodiment.

The cooling device 3 of the fifth embodiment differs from the cooling device 3 of the first embodiment in the guide part 32, which is provided with yet another guide wall 32e (a third guide wall) between the guide walls 32a and 32c, as illustrated in FIG. 25. The third guide wall 32e creates two separate guide areas 32i.

In addition, in the guide plate 33, two guide slits 33g penetrating the guide plate 33 from the front surface 33e to the rear surface 33f are formed in such a manner as to correspond to the two guide areas 32i, as illustrated in FIG. 26. That is, in plan view, the guide plate 33 has the guide slits 33g, one of which is formed in an area overlapping the guide area 32i sandwiched between the guide walls 32a and 32e and the other of which is formed in an area overlapping the guide area 32i sandwiched between the guide walls 32c and 32e.

Also in this case, the guide slits 33g are formed on the guide plate 33 in such a manner that, when the guide plate 33 is placed on the guide part 32, each of the guide slits 33g extends, in plan view, in a straight line toward the tip wall 32d from the inlet 32b to just before the tip wall 32d. The width (in the ±Y direction) of each of the guide slits 33g is preferably the same as in the first embodiment. However, because the space for providing the two guide slits 33g is limited, the width may be narrower than that of the first embodiment. Here, the width may be, for example, 1 mm.

The two guide areas 32i of the fifth embodiment also become smaller as they move away from the inlet 31g of the pool part 31 when viewed in the inflow direction from the inlet 31g toward the guide areas 32i. This configuration allows the pressure difference in the refrigerant having entered each of the guide areas 32i between the tip wall 32d side and the inlet 32b side to be reduced, which facilitates the refrigerant to flow out from each of the two guide slits 33g of the guide plate 33. Therefore, the refrigerant having flowed into the guide areas 32i flows out substantially uniformly from each of the two entire guide slits 33g. This in turn reduces variations in the heat dissipation performance depending on the position on the front surface 15e of the heat dissipation plate 15, and thus uniformly cools the semiconductor unit 2. As a result, it is possible to keep the cost of driving the pump down and also reduce the loss of reliability of the semiconductor device 1. Note that the protrusions 32g of the third and fourth embodiments may be provided on the guide walls 32a, 32c, and 32e. This allows the refrigerant having flowed into the guide areas 32i to flow out substantially uniformly from each of the two entire guide slits 33g even more reliably.

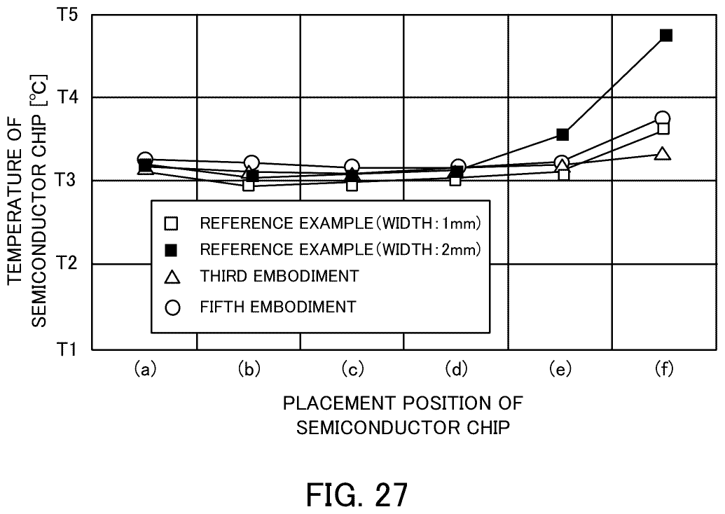

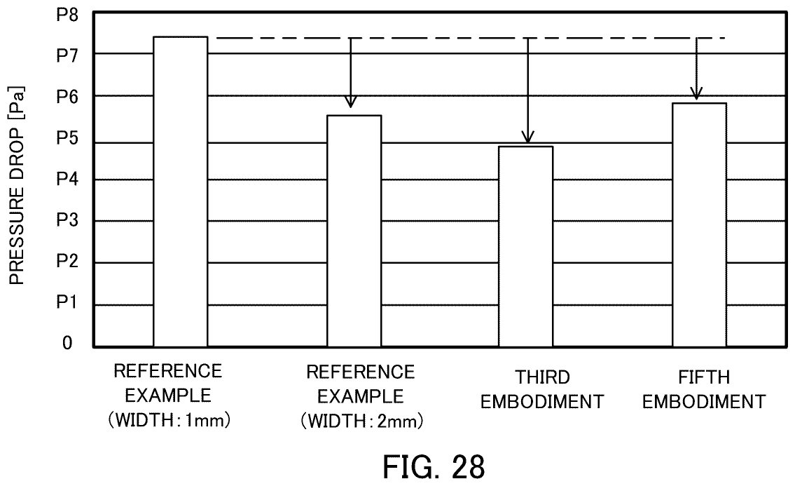

Next described is the heat dissipation performance with reference to FIGS. 27 and 28. Here, the heat dissipation performance achieved by the cooling device 3 of the third and fifth embodiments among the above-described embodiments, as well as the heat dissipation performance achieved by the cooling device 300 of the reference example are examined. FIG. 27 is a graph plotting the temperature of the semiconductor chips relative to their placement positions. FIG. 28 is a graph of pressure drop.

Note that the horizontal axis of FIG. 27 indicates the placement positions of the semiconductor chips 14 while the vertical axis indicates the temperature of the semiconductor chips 14. The placement positions of the semiconductor chips 14 are (a) to (f) assigned to the semiconductor chips 14 of FIG. 1, in order from the short lateral face 15d (the outlet 31h) side toward the short lateral face 15b (the inlet 31g) side. In addition, T1 to T5 on the vertical axis of FIG. 27 represent measured values, which increase from T1 to T5.

Further, FIG. 28 depicts how much pressure drop is reduced compared to the reference example with a slit width of 1 mm. The horizontal axis of FIG. 28 represents the measurement targets while the vertical axis represents the pressure drop ([Pa]), which is the pressure difference in the refrigerant between the outlet 31h and the inlet 31g. Note that P1 to P8 on the vertical axis of FIG. 28 represent measured values, which increase from P1 to P8. The reference example examined here includes two cases in which the width of the guide slit 33g is 1 mm and 2 mm.

Temperature measurements were taken for the semiconductor chips 14 included in the semiconductor unit 2 after being cooled for a predetermined time, using the semiconductor devices each including one of the following cooling devices: the cooling devices 300 according to the two cases of the reference example; and the cooling devices 3 according to the third and fifth embodiments. At this time, the pressure of the refrigerant was also measured at the inlet 31g and at the outlet 31h, and their difference was obtained.

The results illustrated in the graph of FIG. 27 indicate that, in both of the two cases of the reference example, the temperature of the semiconductor chips 14 on the inlet 31g side is higher than that of the semiconductor chips 14 at other positions. That is, in the two cases of the reference example, it is considered that the heat dissipation performance is reduced on the inlet 31g side. When the two cases of the reference example are compared, it can be seen that the decrease in the heat dissipation performance of the semiconductor chips 14 on the inlet 31g side is suppressed in the case with the narrower slit width.

On the other hand, it can be observed that the semiconductor chips 14 at all the positions are cooled almost equally in the third embodiment. The fifth embodiment suppresses the decrease in the heat dissipation performance on the inlet 30g side, compared to the case of the reference example with a slit width of 2 mm.

According to the graph of FIG. 28, the pressure drop is suppressed the most in the third embodiment, and is reduced by about 35% compared to the reference example with a slit width of 1 mm. In the case of the fifth embodiment, the pressure drop is reduced by about 20% compared to the reference example with a slit width of 1 mm.

Therefore, the results illustrated in FIGS. 27 and 28 suggest that the cooling device 3 of the third embodiment enables uniform cooling of the multiple semiconductor chips 14 and sufficiently suppresses pressure drop.

Although not being able to uniformly cool the multiple semiconductor chips 14 compared to the third embodiment, the cooling device 3 of the fifth embodiment exhibits improved heat dissipation capabilities to the same extent as the reference example with a slit width of 1 mm. In addition, the cooling device 3 of the third embodiment suppresses pressure drop more compared to the reference example with a slit width of 2 mm.

According to an aspect, it is possible to suppress an increase in pressure drop in the refrigerant and improve the cooling performance, thereby avoiding the loss of reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip;
a heat dissipation plate, having:
a front surface including a placement area,
a rear surface having a cooling area corresponding to the placement area, and
a plurality of fins provided in the cooling area;
the semiconductor chip being disposed in the placement area;
a pool part, including:
a bottom surface having a rectangular shape in a plan view of the semiconductor device,
a pair of long lateral faces, and
a first short lateral face and a second short lateral face, with an inlet formed on the first short lateral face,
to thereby define a pool space surrounded by the bottom surface, the pair of long lateral faces and the first and second short lateral faces;
a guide part configured to be installed in the pool space on the bottom surface, the guide part having a first end and a second end that are both connected to an inner side of the first short lateral face, at positions opposite to each other across the inlet, so as to separate a guide space from the pool space, the guide space communicating with the inlet; and
a guide plate disposed in the pool space on the guide part, the guide plate having a shape of a flat plate with a slit, wherein
in the plan view of the semiconductor device,
the guide plate is positioned to have two gaps on two opposite sides thereof, respectively between the guide plate and the pair of long lateral faces, and
the slit is formed within an area of the guide plate overlapping the guide space;
the rear surface of the heat dissipation plate is disposed on the pool part in such a manner that the plurality of fins is housed in the pool space and over the guide plate; and
the guide part is installed such that a geometrical area of a cross-section of the guide space becomes smaller as the cross-section is farther away from the inlet of the pool part.

2. The semiconductor device according to claim 1, wherein:
the guide part includes:
a first guide wall having an upstream end and a downstream end, the upstream end thereof constituting the first end of the guide part, the first guide wall being inclined such that the downstream end thereof is closer to a center line passing through a center of the inlet and running parallel to the pair of long lateral faces, than is the upstream end thereof,
a second guide wall having an upstream end and a downstream end, the upstream end thereof constituting the second end of the guide part, the second guide wall being inclined such that the downstream end thereof is closer to the center line than is the upstream end thereof, and
a tip wall which connects the downstream ends of the first guide wall and the second guide wall.

3. The semiconductor device according to claim 2, wherein:
the guide part has a protrusion provided in a vicinity of the inlet in such a manner as to project into the guide space.

4. The semiconductor device according to claim 3, wherein:
the protrusion includes a plurality of protrusions, which is individually provided, on the first guide wall and the second guide wall, at positions opposing each other.

5. The semiconductor device according to claim 4, wherein:
the guide plate has a pair of sub-slits respectively formed on two sides of the slit and running parallel to the slit, and
the pair of sub-slits extend, in the plan view, from the vicinity of the inlet to the protrusions.

6. The semiconductor device according to claim 5, wherein:
each of the pair of sub-slits has a width of 1 mm or more and 4 mm or less.

7. The semiconductor device according to claim 3, wherein:
the protrusion is provided on the bottom surface within the guide space.

8. The semiconductor device according to claim 7, wherein:
the guide plate has a pair of sub-slits respectively formed on two sides of the slit and running parallel to the slit, and
the pair of sub-slits extend, in the plan view, from the vicinity of the inlet to the protrusion.

9. The semiconductor device according to claim 8, wherein:
each of the pair of sub-slits has a width of 1 mm or more and 4 mm or less.

10. The semiconductor device according to claim 1, wherein:
the guide part includes:
a first guide wall which, in the plan view, extends parallel to the pair of long lateral faces, the first guide wall having an upstream end and a downstream end, the upstream end thereof constituting the first end of the guide part,
a second guide wall which extends parallel to the pair of long lateral faces, the second guide wall having an upstream end and a downstream end, the upstream end thereof constituting the second end of the guide part, and
a tip wall which connects the downstream ends of the first guide wall and the second guide wall, and
the bottom surface in the guide space is inclined upward toward the guide plate, such that farther away is a portion of the bottom surface from the inlet, closer is the portion to the guide plate.

11. The semiconductor device according to claim 1, wherein:
the guide part includes:
a first guide wall having an upstream end and a downstream end, the upstream end thereof constituting the first end of the guide part, the first guide wall being inclined such that the downstream end thereof is closer to a center line passing through a center of the inlet and running parallel to the pair of long lateral faces, than is the upstream end thereof,
a second guide wall having an upstream end and a downstream end, the upstream end thereof constituting the second end of the guide part, the second guide wall being inclined such that the downstream end thereof is closer to the center line than is the upstream end thereof,
a third guide wall which is provided on the center line and extends from the inlet, and
a tip wall which connects the downstream ends of the first guide wall and the second guide wall.

12. The semiconductor device according to claim 11, wherein:
the slit of the guide plate includes a plurality of slits, which is individually provided, in the plan view, in
a first area of the guide plate overlapping the guide space sandwiched between the first guide wall and the third guide wall, and
a second area of the guide plate overlapping the guide space sandwiched between the third guide wall and the second guide wall.

13. The semiconductor device according to claim 1, wherein:
the second short lateral face of the pool part has an outlet, opposing the inlet, formed therein.
